(19) United States
(12) Patent Application Publication
(10) Pub. No.: US 2025/0247092 A1
(43) Pub. Date: Jul. 31, 2025

(54) SWITCH CONTROLLER WITH RESONANT GATE DRIVER

(71) Applicant: TEXAS INSTRUMENTS INCORPORATED, Dallas, TX (US)

(72) Inventors: Raveesh MAGOD RAMAKRISHNA, Irving, TX (US); Sombuddha CHAKRABORTY, Redwood City, CA (US); Saket JHA, La Jolla, CA (US)

(21) Appl. No.: 18/428,950

(22) Filed: Jan. 31, 2024

(51) Int. Cl. H03K 17/687; H03K 17/06

(52) U.S. Cl. CPC H03K 17/6871; H03K 17/063; H03K 2217/0063; H03K 2217/0072

(57) ABSTRACT

An apparatus includes: a gate driver circuit having a driver input and a driver output; an inductor coupled to the driver output; a capacitor; a switch coupled between the inductor and the capacitor, the switch having a switch control terminal; and a controller having a gate control input, a switch control output coupled to the switch control terminal, and a gate control output coupled to the driver input. The controller is configured to: responsive to a gate control signal at the gate control input, provide a pulse signal at the switch control output to enable the switch within an interval; and after the interval ends, disable the switch and provide a delayed version of the gate control signal at the gate control output to enable the gate driver circuit.

### BACKGROUND

Power regulation of electronics often involves switches and switch controllers. Gate charge losses during switching operations is a significant contributor to the overall efficiency of power regulation operations. For example, gate charge losses for soft switching field-effect transistors (FETs) at light load currents can be significant.

### SUMMARY

In an example, an apparatus includes: a gate driver circuit having a driver input and a driver output; an inductor coupled to the driver output; a capacitor; a first switch coupled between the inductor and the capacitor, the first switch having a first switch control terminal; a second switch coupled between inductor and the driver output, the second switch having a second switch control terminal; and a controller having a gate control input, a first switch control output, a second switch control output, and a gate control output. The first switch control output is coupled to the first switch control terminal. The second switch control output is coupled to the second switch control terminal. The gate control output is coupled to the driver output.

In another example, an apparatus includes: a power converter having a power converter switch, the power converter switch having a power converter switch control terminal; and a power converter control circuit coupled to the power converter switch control terminal. The power converter control circuit includes: a gate driver circuit having a driver input and a driver output; an inductor coupled to the driver output; a capacitor; a first switch coupled between the inductor and the capacitor, the first switch having a first switch control terminal; a second switch coupled between inductor and the driver output, the second switch having a second switch control terminal; and a gate drive controller having a gate control input, a first switch control output, a second switch control output, and a gate control output. The first switch control output is coupled to the first switch control terminal. The second switch control output is coupled to the second switch control terminal. The gate control output is coupled to the driver output.

In yet another example, a method includes: receiving a first gate control signal having a first transition from a first state to a second state; responsive to the first transition, charging a transistor gate to a first voltage within a first interval using an inductor and a capacitor; after the first interval ends, charging the transistor gate to a second voltage by a pull-up driver circuit; receiving a second gate control signal having a second transition from the second state to the first state; responsive to the second transition, discharging the transistor gate to a third voltage within a second interval using the inductor and the capacitor; and after the second interval ends, discharging the transistor gate to a fourth voltage using a pull-down driver circuit.

### BRIEF DESCRIPTION OF THE DRAWINGS

FIG. 1 is a schematic diagram showing examples of a power conversion system including a resonant gate driver.

FIG. 2 is a schematic diagram showing examples of another power conversion system including a resonant gate driver.

FIG. 3 is graph representing operations of a power conversion system switch.

FIGS. 4 and 5 are schematic diagrams showing example resonant gate drivers for a power conversion system.

FIG. 6 is a graph representing operations of an example resonant gate driver.

FIGS. 7 and 8 are schematic diagrams showing other example resonant gate drivers for a power conversion system.

FIG. 9 is graph representing operations of an example power conversion system.

FIGS. 10 and 11 are schematic diagrams showing example control loop components for a resonant gate driver.

FIGS. 12 and 13 are graphs representing operations of an example power conversion system.

FIG. 14 is a flowchart illustrating an example control method for a power conversion system.

FIG. 15 is a flowchart illustrating an example control method for a power conversion system.

FIG. 16 is graph showing efficiency of an example power converter with and without using the examples of resonant gate driver described herein.

### DETAILED DESCRIPTION

The same reference numbers or other reference designators are used in the drawings to designate the same or similar features. Such features may be the same or similar either by function and/or structure.

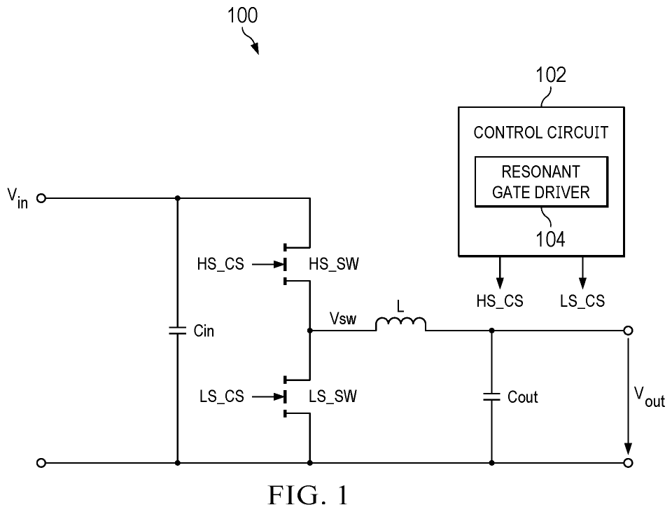

FIG. 1 is a schematic diagram showing examples of a power conversion system 100 including a resonant gate driver 104. The power conversion system 100 includes a half-bridge circuit and a control circuit 102. The power conversion system 100 in FIG. 1 can be a buck converter. The buck converter includes an input capacitor Cin, the half-bridge circuit including a high-side switch HS_SW and a low-side switch LS_SW, an inductor L, and an output capacitor Cout. With the buck converter, an input voltage Vin is converted to an output voltage Vout responsive to control of the high-side switch HS_SW and the low-side switch LS_SW by the control circuit 102.

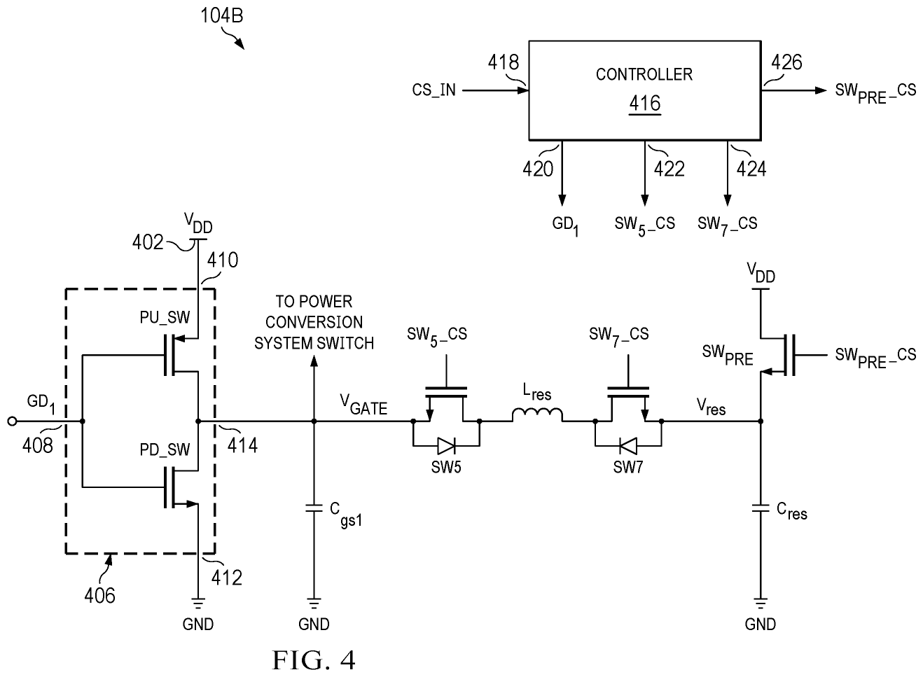

As shown, the control circuit 102 includes the resonant gate driver 104. The control circuit 102 operates to: provide a high-side control signal HS_CS to a control terminal of the high-side switch HS_SW to control the high-side switch HS_SW; and provide a low-side control signal LS_CS to a control terminal of the low-side switch LS_SW to control the low-side switch LS_SW. In some examples, the resonant gate driver 104 includes an inductor, a capacitor, switches, and a controller for the switches. Example resonant gate drivers and/or related control components are illustrated in FIGS. 4, 5, 7, 8, 10, 11. The operations of the resonant gate driver 104 enable some of the gate energy applied to the low-side switch LS_SW and/or the high-side switch HS_SW to be recycled, which improves efficiency of the power conversion system 100.

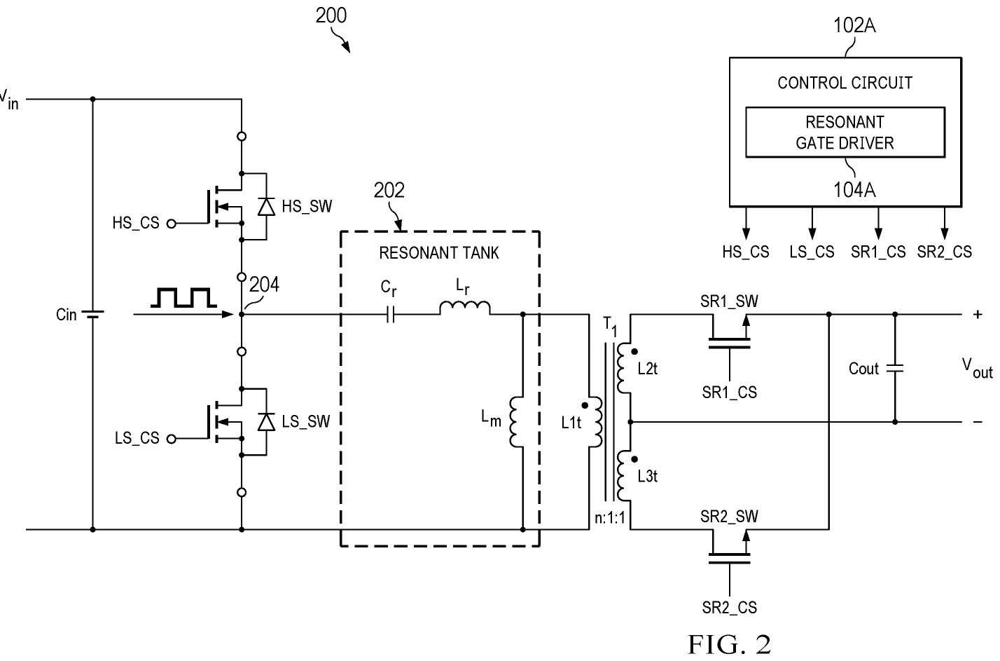

FIG. 2 is a schematic diagram showing examples of another power conversion system 200 including a resonant gate driver 104A. The power conversion system 200 includes a resonant converter and a control circuit 102A. The resonant converter includes a half-bridge converter topology with an input capacitor Cin, a high-side switch HS_SW, a low-side switch LS_SW, and a switch node 204 between the high-side switch HS_SW and the low-side switch LS_SW. The resonant converter also includes a resonant tank 202, a transformer T₁, a first synchronous rectifier switch SR1_SW, a second synchronous rectifier switch SR2_SW, and an output capacitor Cout. The control circuit 102A includes the resonant gate driver 104A. With the resonant converter and control circuit 102A, an input voltage Vin is converted to an output voltage Vout responsive to control of the high-side switch HS_SW, the low-side switch LS_SW, the first synchronous rectifier switch SR1_SW, the second synchronous rectifier switch SR2_SW by the control circuit 102A, and related operations of the resonant tank 202 and the transformer T₁.

In the example of FIG. 2, the resonant tank 202 includes a capacitor Cr, an inductor Lr, and an inductor Lm in the arrangement shown. The transformer T₁ includes a primary-side coil L1t, a first secondary-side coil L2t, and a second secondary-side coil L3t. In some examples, the numbers of turns of the primary-side coil L1t, the first secondary-side coil L2t, and the second secondary-side coil L3t has the relationship n: 1:1, where n is an integer equal to 1 or more. As shown, the resonant tank 202 includes the capacitor Cr and the inductor Lr in series between the switch node 204 and the primary-side inductor L1t. The inductor Lm is in parallel with the primary-side inductor L1t. The first synchronous rectifier switch SR1_SW is between a first terminal of the first secondary-side inductor L2t and a first terminal of the output capacitor Cout. The second synchronous rectifier switch SR2_SW is between a first terminal of the second secondary-side inductor L3t and the first terminal of the output capacitor Cout. The second terminals of the first secondary-side inductor L2t and the second secondary-side inductor L3t are coupled to the second terminal of the output capacitor Cout.

The control circuit 102A operates to: provide the high-side control signal HS_CS to control the high-side switch HS_SW; provide the low-side control signal LS_CS to control the low-side switch LS_SW; provide a gate control signal SR1_CS to control the first synchronous rectifier switch SR1_SW; and provide a second gate control signal SR2_CS to control the second synchronous rectifier switch SR2_SW. The control circuit 102A can enable switch SR1_SW when disabling switch SR2_SW, and enable switch SR2_SW when disabling switch SR1_SW. In some examples, the resonant gate driver 104A includes an inductor, a capacitor, switches, and a controller. Example resonant gate drivers and/or related control components are illustrated in FIGS. 4, 5, 7, 8, 10, 11. The operations of the resonant gate driver 104A enable some of the gate energy applied to the first synchronous rectifier switch SR1_SW and/or the second synchronous rectifier switch SR2_SW to be recycled, which improves efficiency of the power conversion system 200.

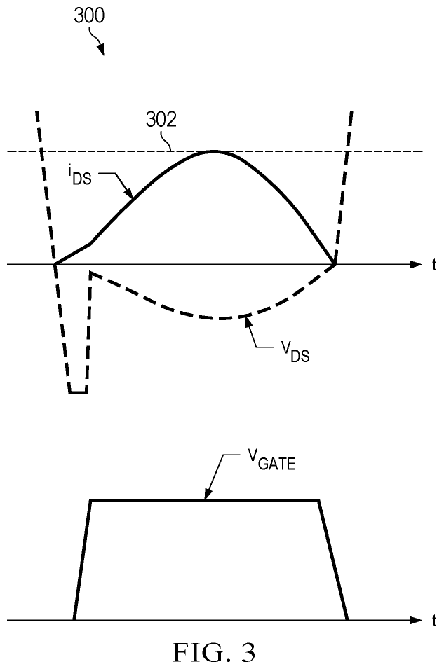

FIG. 3 includes graph 300 representing operations of an example power conversion system switch. The power conversion system switch may be, for example, the low-side switch LS_SW in FIG. 1, the first synchronous rectifier switch SR1_SW in FIG. 2, or the second synchronous rectifier switch SR2_SW in FIG. 2. In the example of FIG. 3, the graph 300 includes waveforms for a drain-to-source voltage (VDs), a drain-to-source current (iDs), and a gate voltage (VGATE) of a power conversion system switch. As shown in graph 300, when VGATE is asserted, ips increases to a max 302, then decreases. Meanwhile, VDs corresponds to body diode conduction while iDs is above zero. During operations of a power conversion system switch losses may include conduction losses, gate switching losses, body diode losses, and drain-to-source capacitance (Coss) losses. For a soft-switching switch, where switching occurs when Vos is close to zero, gate switching loss is substantial compared with conduction loss, body loss, and Coss loss. The significance of gate switching loss can further increase during light load conditions (e.g., below 30-40% of peak power). With a resonant gate driver (e.g., the resonant gate driver 104 in FIG. 1, or the resonant gate driver 104A in FIG. 2), gate switching losses of a power conversion system switch can be reduced, which can improve the efficiency of driving a switch, especially a soft-switching switch under light load conditions.

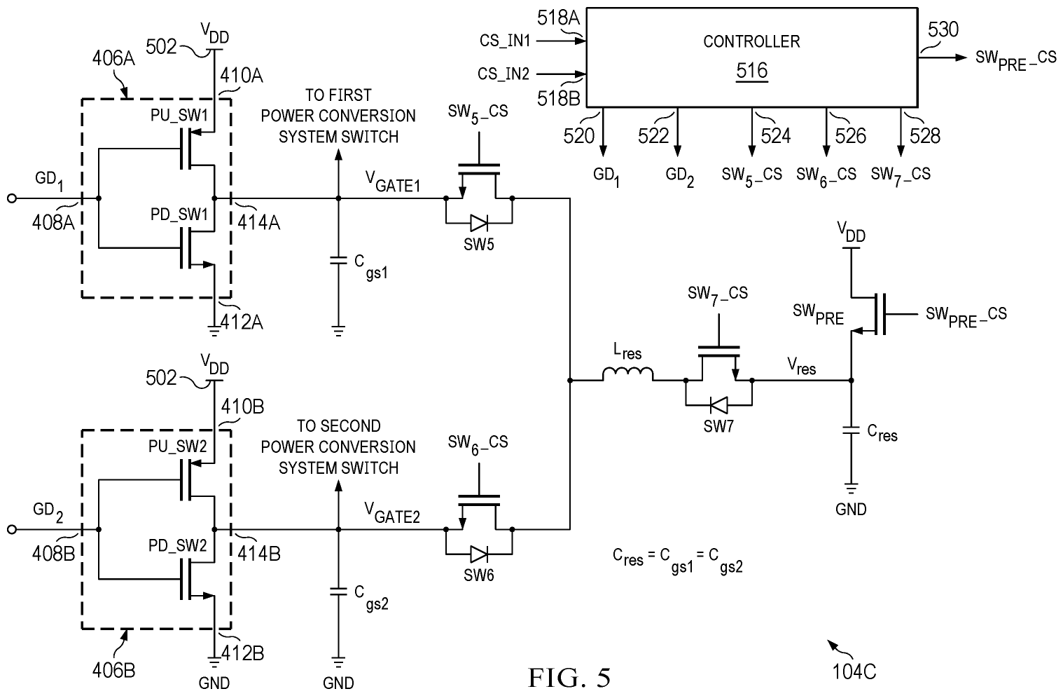

FIGS. 4 and 5 are diagrams showing example resonant gate drivers 104B and 104C for a power conversion system (e.g., the power conversion system 100 in FIG. 1, or the power conversion system 200 in FIG. 2). The resonant gate driver 104B of FIG. 4 is an example of the resonant gate driver 104 in FIG. 1. In the example of FIG. 4, the resonant gate driver 104B includes a driver circuit 406 (sometimes referred to as a gate driver circuit herein) having a first terminal 408, a second terminal 410, a third terminal 412, and a fourth terminal 414. The driver circuit 406 includes a pull-up switch PU_SW and a pull-down switch PD_SW coupled in series between the second terminal 410 and the third terminal 412. The resonant gate driver 104B also includes a first switch SW5, an inductor Lᵣₑₛ, a second switch SW7, a pre-charge switch SW_{PRE}, a capacitor Cᵣₑₛ, and a controller 416. Inductor Lᵣₑₛ and capacitor Cᵣₑₛ can form a resonant network to provide a resonant gate driver. C_{GS1} can represent the gate-source capacitance of a transistor configured as a power conversion system switch, such as a half-bridge switch (e.g., LS_SW and/or HS_SW of FIG. 1), a synchronous rectifier switch (e.g., SR1_SW and/or SR2_SW of FIG. 2), etc. In some examples, Cᵣₑₛ can have similar capacitance as CGSt. Each of the first switch SW5, the inductor Lᵣₑₛ, the second switch SW7, the pre-charge switch SW_{PRE} and the capacitor Cᵣₑₛ has a first terminal and a second terminal. Each of the first switch SW5, the second switch SW7, and the pre-charge switch SW_{PRE} can include a transistor having a respective control terminal. In some examples, the first switch SW5 and second switch SW7 can have back-to-back body diodes as shown in FIG. 4 so that the body diodes of the switches do not conduct in any phase of the operation to be described below. The controller 416 has a first terminal 418, a second terminal 420, a third terminal 422, a fourth terminal 424, and a fifth terminal 426.

The first terminal 408 of the driver circuit 406 is coupled to the second terminal 420 of the controller 416 and to the control terminals of the pull-up switch PU_SW and the pull-down switch PD_SW. The second terminal 410 (sometimes referred to as a power terminal herein) of the driver circuit 406 is coupled to a source voltage (V_{DD}) terminal 402 and to a first terminal of the pull-up switch PU_SW. The second terminal of the pull-up switch PU_SW is coupled to the first terminal of the pull-down switch PD_SW and to the fourth terminal 414 of the driver circuit 406. The third terminal 412 of the driver circuit 406 is coupled to ground or a ground terminal and to the second terminal of the pull-down switch PD_SW.

The fourth terminal 414 of the driver circuit 406 is coupled to a control terminal of a transistor having the C_{gs1} capacitance, and to the first terminal of the first switch SW5. The control terminal of the first switch SW5 is coupled to the third terminal 422 of the controller 416. The second terminal of the first switch SW5 is coupled to the first terminal of the inductor Lᵣₑₛ. The second terminal of the inductor Lᵣₑₛ is coupled to the first terminal of the second switch SW7. The control terminal of the second switch SW7 is coupled to the fourth terminal 424 of the controller 416. The second terminal of the second switch SW7 is coupled to the first terminal of the capacitor Cᵣₑₛ. The first terminal of the pre-charge switch SW_{PRE} is coupled to the V_{DD} terminal 402. The control terminal of the pre-charge switch SW_{PRE} is coupled to the fifth terminal 426 of the controller 416. The second terminal of the pre-charge switch SW_{PRE} is coupled to the first terminal of the capacitor Cᵣₑₛ. The second terminal of the capacitor Cᵣₑₛ is coupled to ground or a ground terminal. As to be described below, the first switch SW5 can be enabled to charge or discharge the C_{gs1} capacitance using the resonant network including inductor Lᵣₑₛ and capacitor Cᵣₑₛ to increase/decrease the gate voltage of the transistor (Vgate) to turn on/off the transistor, followed by enabling of driver circuit 406 to further charge/discharge the C_{gs1} capacitance to further increase/decrease Vgate, or to maintain Vgate at a particular state (e.g., a ground voltage, the V_{DD} voltage, etc.) to maintain the transistor in the on-state or the off-state.

In operation, the resonant gate driver 104B receives a gate control signal CS_IN (e.g., HS_CS or LS_CS of FIGS. 1 and 2, SR1_CS or SR2_CS of FIG. 2) at the first terminal 418 and controls the voltage (Vgate) at the C_{gs1} capacitance responsive to the control signal CS_IN by selectively: connecting the control terminal of the power conversion system switch (represented by C_{gs1}) to V_{DD} or ground using the driver circuit 406; connecting the control terminal of the power conversion system switch to the inductor Lᵣₑₛ via the first switch SW5; and connecting the control terminal of the power conversion system switch to the capacitor Cᵣₑₛ via inductor Lᵣₑₛ using first switch SW5 and the second switch SW7. Vgate sets a state of the power conversion system switch, such as those described herein.

In some examples, the controller 416 performs a pre-charge operation in which the capacitor Cᵣₑₛ is charged to V_{DD} (and Vres=V_{DD}) by turning on the pre-charge switch SW_{PRE} using SW_{PRE}_CS, while the first switch SW5 and the second switch SW7 are off. After the pre-charge operation, the controller 416 performs a first charge transfer operation responsive to the CS_IN signal indicating that the power conversion system switch is to be turned on. During the first charge transfer operation, the driver circuit 406 is off, the first switch SW5 is turned on by SW₅_CS, the second switch SW7 is turned on by SW₇_CS, and the pre-charge switch SW_{PRE} is off. During the first charge transfer operation, charge is transferred to C_{gs1} capacitance by the inductor Lᵣₑₛ and the capacitor Cᵣₑₛ, and Vgate increases due to charging of the C_{gs1} capacitance. Due to losses, at the end of the first charge transfer operation, Vgate can be lower than V_{DD}. After the first charge transfer operation, the controller 416 performs a pull-up operation in which the pull-up switch PU_SW of the driver circuit 406 is turned on by GD₁, while the first switch SW5, the second switch SW7, and the pre-charge switch SW_{PRE} are off. During the pull-up operation, Vgate is increased to V_{DD}, and the power conversion system switch can have a first state (e.g., an on state).

Responsive to the CS_IN signal indicating that the power conversion system switch is to be turned off, the controller 416 performs a second charge transfer operation in which the driver circuit 406 is off, the first switch SW5 is turned on by SW₅_CS, the second switch SW7 is turned on by SW₇_CS, and the pre-charge switch SW_{PRE} is off. During the second charge transfer operation, the charge on the C_{gs1} capacitance is transferred to the capacitor Cᵣₑₛ via the inductor Lᵣₑₛ, and Vgate voltage decreases due to discharging of the C_{gs1} capacitance. At least some of the charge transferred out of the C_{gs1} capacitance can include the charge previously provided by the capacitor Cᵣₑₛ via the inductor Lᵣₑₛ in the first charge transfer operation, hence the charge is recycled. Due to losses, at the end of the second charge transfer operation Vᵣₑₛ can be higher than the ground voltage. After the second charge transfer operation, the controller 416 performs a pull-down operation in which the pull-down switch PD_SW of the driver circuit 406 is turned on by GD₁, while the first switch SW5, the second switch SW7, and the pre-charge switch SW_{PRE} are off. During the pull-down operation, any remaining charge on the C_{gs1} capacitance after the second charge transfer operation can be removed (Vgate voltage can be grounded during the pull-down operation), and the power conversion system switch can be in a second state (e.g., an off state).

The resonant gate driver 104B and related charge transfer operations enables some recycling of the charge/energy used in charging/discharging the power conversion system switch. Also, most of the charge transfer is performed by the resonant network including Cᵣₑₛ and Lᵣₑₛ, which can be lossless or have very little loss, and only a small amount of charge transfer is performed via the resistive paths of the pull-up switch PU_SW and the pull-down switch PD_SW of the driver circuit 406, which can reduce the switching loss associated with charging/discharging of the C_{GS} capacitance of the power conversion system switch. Further, with the back-to-back diode arrangement of the first switch SW5 and the second switch SW7, charging of the inductor Lᵣₑₛ by the driver circuit 406 is avoided, which reduces charge loss through the resistive path of the driver circuit 406. All these can reduce the gate switching loss and improve the efficiency of a power conversion system, especially for a power conversion system having a soft-switching switch and operating in a light load condition.

The resonant gate driver 104C of FIG. 5 is an example of the resonant gate driver 104A in FIG. 2. In the example of FIG. 5, the resonant gate driver 104C includes a first driver circuit 406A and a second driver circuit 406B. The first driver circuit 406A has a first terminal 408A, a second terminal 410A, a third terminal 412A, and a fourth terminal 414A. The second driver circuit 406B has a first terminal 408B, a second terminal 410B, a third terminal 412B, and a fourth terminal 414B. The first driver circuit 406A includes a first pull-up switch PU_SW1 and a first pull-down switch PD_SW1 in series between the second terminal 410A and the third terminal 412A. The second driver circuit 406B includes a second pull-up switch PU_SW2 and a second pull-down switch PD_SW2 in series between the second terminal 410B and the third terminal 412B.

In some examples, the inductor Lᵣₑₛ, the capacitor Cᵣₑₛ, the driver circuit 406, the first switch SW5, and the second switch SW7 in FIG. 4 are part of an integrated circuit (IC). In such examples, the IC may include a semiconductor substrate on a routable lead frame (RLF). Also, the inductor Lᵣₑₛ can be in the RLF, and the capacitor Cᵣₑₛ can be a trench capacitor in the semiconductor substrate.

In the example of FIG. 5, the resonant gate driver 104B includes the first switch SW5, the inductor Lᵣₑₛ, the second switch SW7, the pre-charge switch SW_{PRE}, and the capacitor Cᵣₑₛ. The resonant gate driver 104B also includes a third switch SW6 and a controller 516. Each of the first switch SW5, the inductor Lᵣₑₛ, the second switch SW7, the third switch SW6, the pre-charge switch SW_{PRE} and the capacitor Cᵣₑₛ has a first terminal and a second terminal. Each of the first switch SW5, the second switch SW7, the third switch SW6, and the pre-charge switch SW_{PRE} also has a respective control terminal. The controller 516 has first terminals 518A and 518B, a second terminal 520, a third terminal 522, a fourth terminal 524, and a fifth terminal 526, a sixth terminal 528, and a seventh terminal 530.

The first terminal 408A of the first driver circuit 406A is coupled to the second terminal 520 of the controller 516 and to the control terminals of the first pull-up switch PU_SW1 and the first pull-down switch PD_SW1. The second terminal 410A of the first driver circuit 406A is coupled to a V_{DD} terminal 502 and to a first terminal of the first pull-up switch PU_SW1. The second terminal of the first pull-up switch PU_SW1 is coupled to the first terminal of the first pull-down switch PD_SW1 and to the fourth terminal 414A of the first driver circuit 406A. The third terminal 412A of the first driver circuit 406A is coupled to ground or a ground terminal and to the second terminal of the first pull-down switch PD_SW1.

The fourth terminal 414A of the first driver circuit 406A is coupled to a first control terminal of a first power conversion system switch (represented by C_{gs1} capacitance) and to the first terminal of the first switch SW5. The control terminal of the first switch SW5 is coupled to the fourth terminal 524 of the controller 516. The second terminal of the first switch SW5 is coupled to the first terminal of the inductor Lᵣₑₛ. The second terminal of the inductor Lᵣₑₛ is coupled to the first terminal of the second switch SW7. The control terminal of the second switch SW7 is coupled to the fifth terminal 526 of the controller 516. The second terminal of the second switch SW7 is coupled to the first terminal of the capacitor Cᵣₑₛ. The first terminal of the pre-charge switch SW_{PRE} is coupled to the V_{DD} terminal 502. The control terminal of the pre-charge switch SW_{PRE} is coupled to the seventh terminal 530 of the controller 416. The second terminal of the pre-charge switch SW_{PRE} is coupled to the first terminal of the capacitor Cᵣₑₛ. The second terminal of the capacitor Cᵣₑₛ is coupled to ground or a ground terminal.

The first terminal 408B of the second driver circuit 406B is coupled to the third terminal 522 of the controller 516 and to the control terminals of the second pull-up switch PU_SW2 and the second pull-down switch PD_SW2. The second terminal 410B of the second driver circuit 406B is coupled to the V_{DD} terminal 502 and to the first terminal of the second pull-up switch PU_SW2. The second terminal of the second pull-up switch PU_SW2 is coupled to the first terminal of the second pull-down switch PD_SW2 and to the fourth terminal 414B of the second driver circuit 406B. The third terminal 412B of the second driver circuit 406B is coupled to ground or a ground terminal and to the second terminal of the second pull-down switch PD_SW2.

The fourth terminal 414B of the second driver circuit 406B is coupled to a second control terminal of a second power conversion system switch (represented by C_{gs2} capacitance) and to the first terminal of the third switch SW6. Also, the control terminal of the third switch SW6 is coupled to the sixth terminal 528 of the controller 516. The second terminal of the third switch SW6 is coupled to the first terminal of the inductor Lᵣₑₛ. In some examples, Cᵣₑₛ can have similar capacitance as the C_{GS1} capacitance and the C_{GS2} capacitance.

In operation, the resonant gate driver 104C receives a first gate control signal CS_IN1 (e.g., HS_CS of FIGS. 1 and 2, SR1_CS of FIG. 2) at the first terminal 518A, and controls a first voltage (Vgate1) at the first control terminal of the first power conversion system switch (represented by the C_{gs1} capacitance) by selectively: connecting the first control terminal of the first power conversion system switch connecting the first control terminal of the first power conversion system switch to the inductor Lᵣₑₛ via the first switch SW5; and connecting the first control terminal of the first power conversion system switch to the capacitor Cᵣₑₛ via inductor Lᵣₑₛ using the first switch SW5 and the second switch SW7. Vgate1 is used to set the state of the first power conversion system switch, such as those described herein.

The resonant gate driver 104C receives a second gate control signal CS_IN2 (e.g., LS_CS of FIGS. 1 and 2, SR2_CS of FIG. 2) at the first terminal 518A and controls a second voltage (Vgate2) at the second control terminal of the second power conversion system switch (represented by the C_{gs2} capacitance) by selectively: connecting the second control terminal of the second power conversion system switch to V_{DD} or ground using the second driver circuit 406B; connecting the second control terminal of the second power conversion system switch to the inductor Lᵣₑₛ via the third switch SW6; and connecting the second control terminal of the second power conversion system switch to the capacitor Cᵣₑₛ via inductor Lᵣₑₛ using second switch SW7 and the third switch SW6. Vgate2 is used to set the state of the second power conversion system switch, such as those described herein.

In some examples, the controller 516 performs a pre-charge operation in which the capacitor Cᵣₑₛ is charged to V_{DD}, with Vᵣₑₛ=V_{DD}, by turning on the pre-charge switch SW_{PRE} using SW_{PRE}_CS, while the first switch SW5, the second switch SW7, and the third switch SW6 are off. After the pre-charge operation and responsive to CS_IN1 indicating the first power conversion system switch is to be turned on, the controller 516 performs a first charge transfer operation in which the first driver circuit 406A and the second driver circuit 406B are off, the first switch SW5 is turned on by SW₅_CS, the second switch SW7 is turned on by SW₇_CS, and the pre-charge switch SW_{PRE} is off. During the first charge transfer operation, charge is transferred to the C_{gs1} capacitance via the inductor Lᵣₑₛ. Due to losses, after the first charge transfer operation, the Vgate1 voltage can be less than V_{DD}. After the first charge transfer operation, the controller 516 performs a first pull-up operation in which the first pull-up switch PU_SW1 of the first driver circuit 406A is turned on by GD₁, while the first switch SW5, the second switch SW7, the third switch SW6, and the pre-charge switch SW_{PRE} are off. During the first pull-up operation, Vgate1 is increased to V_{DD} and the first power conversion system switch can have a first state (e.g., an on state).

Responsive to CS_IN1 indicating the first power conversion system switch is to be turned off, the controller 516 performs a second charge transfer operation in which the first driver circuit 406A and the second driver circuit 406B are off, the first switch SW5 is turned on by SW₅_CS, the second switch SW7 is turned on by SW₇_CS, the third switch SW6 is off, and the pre-charge switch SW_{PRE} is off. During the second charge transfer operation, the charge on the C_{gs1} capacitance is transferred to the capacitor Cᵣₑₛ via the inductor Lᵣₑₛ. Due to losses, the second charge transfer operation results in Vᵣₑₛ being higher than the ground voltage. After the second charge transfer operation, the controller 516 performs a first pull-down operation in which the first pull-down switch PD_SW1 of the first driver circuit 406A is turned on by GD₁, while the first switch SW5, the second switch SW7, the third switch SW6, and the pre-charge switch SW_{PRE} are off. During the first pull-down operation, any remaining charge on the C_{gs1} capacitance after the second charge transfer operation is removed, and Vgate1 can become grounded. While Vgate1 is grounded during the pull-down operation, the first power conversion system switch related to the C_{gs1} capacitance has a second state (e.g., an off state). As described in FIG. 4, the resonant gate driver 104C and related charge transfer operations enables some recycling of charge used in charging/discharging of the C_{gs1} capacitance, which improves efficiency of a power conversion system. With the back-to-back diode arrangement of the first switch SW5 and the second switch SW7, charging the inductor Lᵣₑₛ by the first driver circuit 406A is avoided, which reduces charge loss through the resistive path of the first driver circuit 406A.

Responsive to CS_IN2 indicating that the second power conversion system switch is to be turned on, the controller 516 performs a third charge transfer operation in which the first driver circuit 406A and the second driver circuit 406B are off, the first switch SW5 is off, the second switch SW7 is turned on by SW₇_CS, the third switch SW6 is turned on SW₆_CS, and the pre-charge switch SW_{PRE} is off. During the third charge transfer operation, charge is transferred to the C_{gs2} capacitance via the inductor Lᵣₑₛ. Due to losses, after the third charge transfer operation ends, the Vgate2 voltage can be lower than V_{DD}. After the third charge transfer operation, the controller 516 performs a second pull-up operation in which the second pull-up switch PU_SW2 of the second driver circuit 406B is turned on by GD₂, while the first switch SW5, the second switch SW7, the third switch SW6, and the pre-charge switch SW_{PRE} are off. During the second pull-up operation, Vgate2 is increased to V_{DD} and the second power conversion system switch can have a first state (e.g., an on state).

Responsive to CS_IN2 indicating that the second power conversion system switch is to be turned off, the controller 516 performs a fourth charge transfer operation in which the first driver circuit 406A and the second driver circuit 406B are off, the first switch SW5 is off, the third switch SW6 is turned on by SW₆_CS, the second switch SW7 is turned on by SW₇_CS, and the pre-charge switch SW_{PRE} is off. During the fourth charge transfer operation, the charge of the C_{gs2} capacitance is transferred to the capacitor Cᵣₑₛ via the inductor Lᵣₑₛ. Due to losses, at the end of the fourth charge transfer operation, Vᵣₑₛ can be higher than the ground voltage. After the fourth charge transfer operation, the controller 516 performs a second pull-down operation in which the second pull-down switch PD_SW2 of the second driver circuit 406B is turned on by GD₂, while the first switch SW5, the second switch SW7, the third switch SW6, and the pre-charge switch SW_{PRE} are off. During the second pull-down operation, any remaining charge on the C_{gs2} capacitance after the fourth charge transfer operation is removed, and Vgate2 can be grounded. While Vgate2 is grounded during the pull-down operation, the second power conversion system switch can have a second state (e.g., an off state).

In some examples, the first and second charge transfer operations can occur within a first interval, the third and fourth charge transfer operations can occur within a second interval that do not overlap with the first interval, so that the first and second power conversion system switches are turned on at different and non-overlapping intervals.

The resonant gate driver 104C and related charge transfer operations enables some recycling of charge used in charging/discharging of the C_{gs2} capacitance, which improves efficiency of a power conversion system. With the back-to-back diode arrangement of the third switch SW6 and the second switch SW7, charging the inductor Lᵣₑₛ by the second driver circuit 406B is avoided, which reduces charge loss through the resistive path of the second driver circuit 406B.

In some examples, the inductor Lᵣₑₛ, the capacitor Cᵣₑₛ, the first driver circuit 406A, the second driver circuit 406B, the first switch SW5, the second switch SW7, and the third switch SW6 in FIG. 5 are part of an IC. In such examples, the IC may include a semiconductor substrate on an RLF. Also, the inductor Lᵣₑₛ can be in the RLF, and the capacitor Cᵣₑₛ can be a trench capacitor in the semiconductor substrate.

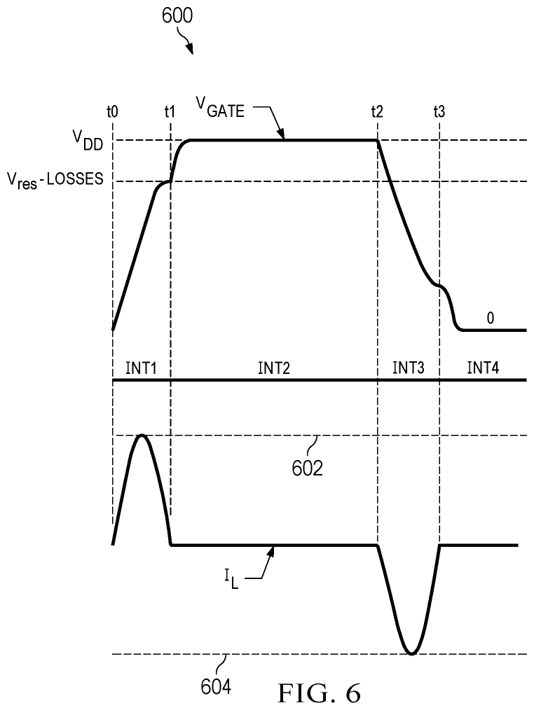

FIG. 6 is a graph 600 representing operations of an example resonant gate driver (e.g., the resonant gate driver 104 in FIG. 1, the resonant gate driver 104A in FIG. 2, the resonant gate driver 104B in FIG. 4, or the resonant gate driver 104C in FIG. 5). The graph 600 includes a first interval INT1, a second interval INT2, a third interval INT3, and a fourth INT4. The first interval INT1 corresponds to first charge transfer operation or a third charge transfer operation as described in FIGS. 4 and 5. The second interval INT2 corresponds to a pull-up operation (e.g., the pull-up operation in FIG. 4, the first pull-up operation in FIG. 5, or the second pull-up operation in FIG. 5) as described in FIGS. 4 and 5. The third interval INT3 corresponds to a second charge transfer operation or a fourth charge transfer operation as described in FIGS. 4 and 5. The fourth interval INT4 corresponds to a pull-down operation (e.g., the pull-down operation in FIG. 4, the first pull-down operation in FIG. 5, or the second pull-down operation in FIG. 5) described in FIGS. 4 and 5.

In graph 600, Vgate and the current of inductor Lᵣₑₛ (I_{L}) are illustrated for each of the first interval INT1, the second interval INT2, the third interval INT3, and the fourth interval INT4. Vgate corresponds to Vgate as described in FIG. 1, Vgate1 as described in FIG. 5, or Vgate2 as described in FIG. 5. Also, graph 600 assumes Cᵣₑₛ is pre-charged to V_{DD}, with Vres=V_{DD}. As shown, during the first interval INT1, I_{L} increases to a positive current 602 before falling to zero. The current through I_{L} during the first interval INT1 is used to increase Vgate from zero to Vres−losses. During the second interval INT2, Vgate increases from Vres−losses to V_{DD} due to pull-up operations, and I_{L} is zero (e.g., due to first switch SW5 and the third switch SW6 being off and/or due to the second switch SW7 being off). During the second interval INT2, a power conversion system switch may be turned on using Vgate as described herein. During the third interval INT3, I_{L} decreases to a negative current 604 before returning to zero. The current through I_{L} during the third interval INT3 is used to discharge C_{GS1} and decrease Vgate. During the fourth interval INT4, Vgate falls to zero due to pull-down operations, and I_{L} is zero (e.g., due to first switch SW5 and the third switch SW6 being off and/or due to the second switch SW7 being off).

As to be described below, in some examples, a resonant gate driver can include a feedback loop to set the durations (INT1 and INT3 of FIG. 6) of the pulses of SW₅_CS, SW₇_CS (of FIGS. 4 and 5), and SW₆_CS (of FIG. 5), so that the gate driver is engaged (e.g., pull-up switch PU_SW being enabled, pull-down switch PD_SW being enabled) when inductor I_{L} is zero. Such arrangements can reduce the amount of charge conducted by the gate driver to further charge/discharge the C_{GS1} capacitance and reduce the gate switching losses. Specifically, referring to FIG. 6, if the pulses of SW₅_CS, SW₇_CS, and SW₆_CS are shorter than the durations of INT1 and INT3 of FIG. 6, the charge transfer operation ends when inductor I_{L} is positive and the resonant network of Lᵣₑₛ and Cᵣₑₛ is not yet fully discharged. Also, if the pulses of SW₅_CS, SW₇_CS, and SW₆_CS are longer than the durations of INT1 and INT3 of FIG. 6, the charge transfer operation ends when inductor I_{L} is negative and the resonant network of Lᵣₑₛ and Cᵣₑₛ is resonating. In both cases, the amount of charge recycled/recovered from the resonant network become less than the charge provided to the resonant network in the prior charge transfer operation, which increases the amount of charge that flows through the gate driver to further charge/discharge the C_{GS1} capacitance and increases the gate switching loss. Moreover, the correct pulse widths (and correct times of enabling/disabling the first switch SW5, the second switch SW7, and the third switch SW6) to achieve zero I_{L} may depend on various factors, such as the C_{GS1} capacitance and Cᵣₑₛ, the inductances of Lᵣₑₛ, the on-resistances of the first switch SW5, the second switch SW7, and the third switch SW6. Having a feedback control loop to determine the pulse widths based on indicators of zero I_{L} allows more precise control of the pulse widths of SW₅_CS, SW₇_CS, and SW₆_CS, which in turn can further reduce gate switching loss and improve efficiency.

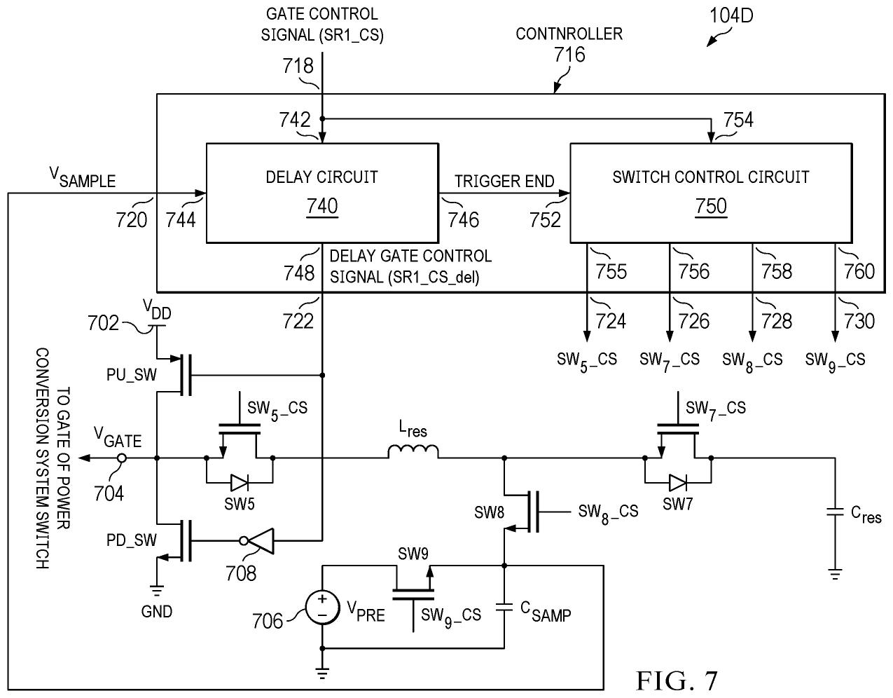

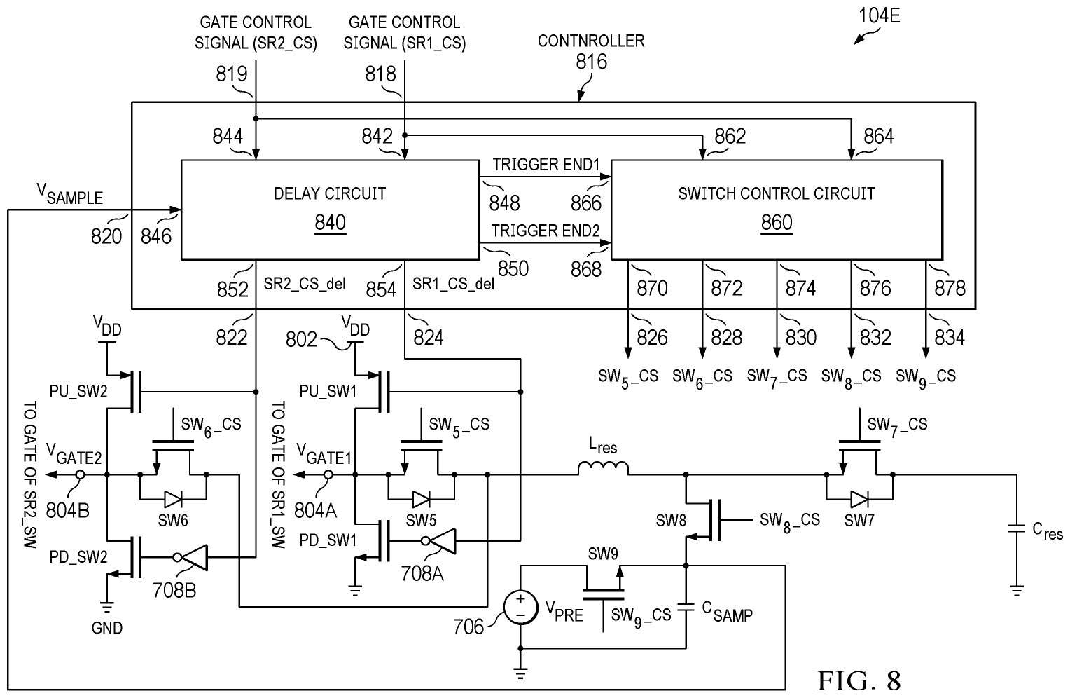

FIGS. 7 and 8 are schematic diagrams showing other example resonant gate drivers 104D and 104E for a power conversion system. The resonant gate driver 104D of FIG. 7 is an example of the resonant gate driver 104 in FIG. 1 and includes some of the components of the resonant gate driver 104B of FIG. 4 including the pull-up switch PU_SW, the pull-down switch PU_SW, the first switch SW5, the inductor Lᵣₑₛ, the second switch SW7, and the capacitor Cᵣₑₛ. The resonant gate driver 104D also includes a fourth switch SW8, a fifth switch SW9, a sampling capacitor C_{SAMP}, a voltage source 706, and an inverter 708. Each of the fourth switch SW8, the fifth switch SW9, the sampling capacitor C_{SAMP}, the voltage source 706, and the inverter 708 has a first terminal and a second terminal. Each of the fourth switch SW8 and the fifth switch SW9 also includes a respective control terminal.

In the example of FIG. 7, the resonant gate driver 104D also includes a controller 716 (sometimes referred to as a gate driver controller herein). The controller 716 has a first terminal 718, a second terminal 720, a third terminal 722, a fourth terminal 724, a fifth terminal 726, a sixth terminal 728, and a seventh terminal 730. In the example of FIG. 7, the controller 716 includes a delay circuit 740 and a switch control circuit 750. The delay circuit 740 has a first terminal 742, a second terminal 744, a third terminal 746, and a fourth terminal 748. The switch control circuit 750 has a first terminal 752, a second terminal 754, a third terminal 755, a fourth terminal 756, a fifth terminal 758, and a sixth terminal 760. In some examples, the resonant gate driver 104D may also include the pre-charge switch SW_{PRE} described in FIGS. 4 and 5. In such case, the controller 716 may include an additional terminal to provide SW_{PRE}_CS.

In the example of FIG. 7, the first terminal of the pull-up switch PU_SW is coupled to a V_{DD} terminal 702. The control terminal of the pull-up switch PU_SW is coupled to the third terminal 722 of the controller 716. The second terminal of the pull-up switch PU_SW is coupled to the first terminal of the pull-down switch PD_SW and a gate terminal 704. The control terminal of the pull-down switch PD_SW is coupled to the second terminal of the inverter 708. The second terminal of the pull-down switch PD_SW is coupled to ground or a ground terminal. The first terminal of the inverter 708 is coupled to the third terminal 722 of the controller 716. The gate terminal 704 is coupled to the first terminal of the first switch SW5. The control terminal of the first switch SW5 is coupled to the fourth terminal 724 of the controller 716. The second terminal of the first switch SW5 is coupled to the first terminal of the inductor Lᵣₑₛ. The second terminal of the inductor Lᵣₑₛ is coupled to the first terminal of the second switch SW7. The control terminal of the second switch SW7 is coupled to the fifth terminal 726 of the controller 716. The second terminal of the second switch SW7 is coupled to the first terminal of the capacitor Cᵣₑₛ. The second terminal of the capacitor Cᵣₑₛ is coupled to ground or a ground terminal.

As shown, the first terminal of the fourth switch SW8 is coupled to the second terminal of the inductor Lᵣₑₛ. The control terminal of the fourth switch SW8 is coupled to the sixth terminal 728 of the controller 716. The second terminal of the fourth switch SW8 is coupled to the first terminal of the fifth switch SW9 and to the first terminal of the capacitor C_{SAMP}. The control terminal of the fifth switch SW9 is coupled to the seventh terminal 730 of the controller 716. The second terminal of the fifth switch SW9 is coupled to the first terminal of the voltage source 706. The second terminal of the voltage source 706 is coupled to ground or a ground terminal.

In the example of FIG. 7, the charge on the capacitor C_{SAMP} is Vsample and is used as a delay control input signal to the controller 716. As shown, the second terminal 720 of the controller 716 is coupled to the first terminal of the capacitor C_{SAMP} and to the second terminal 744 of the delay circuit 740. The first terminal 742 of the delay circuit 740 is coupled to first terminal 718 of the controller 716. The third terminal 746 of the delay circuit 740 is coupled to the first terminal 752 of the switch control circuit 750. The fourth terminal 748 of the delay circuit 740 is coupled to the third terminal 722 of the controller 716. The second terminal 754 of the switch control circuit 750 is coupled to the first terminal 718 of the controller 716. The third terminal 755 of the switch control circuit 750 is coupled to the fourth terminal 724 of the controller 716. The fourth terminal 756 of the switch control circuit 750 is coupled to the fifth terminal 726 of the controller 716. The fifth terminal 758 of the switch control circuit 750 is coupled to the sixth terminal 728 of the controller 716. The sixth terminal 760 of the switch control circuit 750 is coupled to the seventh terminal 730 of the controller 716. As to be described below, delay circuit 740 together with the capacitor C_{SAMP} and the fourth switch SW8 form a feedback control loop to set the pulse widths of SW₅_CS and SW₇_CS to end the charge transfer operation when the inductor current I_{L} is at or close to zero.

In operation, the resonant gate driver 104D controls the voltage (Vgate) at the gate terminal 704 by selectively: connecting the gate terminal 704 to V_{DD} or ground using the pull-up switch PU_SW and the pull-down switch PD_SW; connecting the gate terminal 704 to the inductor Lᵣₑₛ via the first switch SW5; and connecting the gate terminal 704 to the capacitor Cᵣₑₛ via the inductor Lᵣₑₛ using first switch SW5 and the second switch SW7. Vgate is used to control a power conversion system switch having the gate terminal 704, such as those described herein.

In the example of FIG. 7, the controller 716 operates to: receive the gate control signal SR1_CS at the first terminal 718; identify a first transition (e.g., a rising edge) of the gate control signal SR1_CS as a first trigger start signal; control CS₅_CS at the fourth terminal 724 and CS₇_CS at the fifth terminal 726 responsive to the trigger start signal to perform a first charge transfer operation as described herein; generate a first trigger end signal after a predetermined interval has elapsed from the first transition, which signals the end of the first charge transfer operation; after the first charge transfer operation ends, control CS₈_CS at the sixth terminal 728 to sample the voltage of the inductor Iᵣₑₛ using the capacitor C_{SAMP}, resulting in Vsample; provide a delayed gate control signal SR1_CS_del at the third terminal 722 after the interval ends and after sampling ends. Also, after sampling ends, control CS₈_CS at the seventh terminal 730 to reset the charge on the capacitor C_{SAMP} to the voltage level (V_{PRE}) of the voltage source 706.

Also, the controller 716 operates to: identify a second transition (e.g., a falling edge) of the gate control signal SR1_CS as a first trigger start signal control CS₅_CS at the fourth terminal 724 and CS₇_CS at the fifth terminal 726 responsive to the second trigger start signal to control a second charge transfer operation as described herein; generate a second trigger end signal after the predetermined interval has elapsed from the second transition, which signals the end of the second charge transfer operation.

More specifically, the delay circuit 740 operates to: receive the gate control signal SR1_CS having a first transition and a second transition at the first terminal 742; provide a first trigger end signal at the third terminal 746 as a delayed version of the first transition delayed based on the interval, and provide a delayed gate control signal SR1_CS_del at the fourth terminal 748 also by delaying the first transition based on the interval. The delay circuit 740 also operates to receive Vsample at the second terminal 744; adjust the duration of the interval; provide a second trigger end signal at the third terminal 746 as a delayed version of the second transition delayed based on the adjusted interval, and provide a delayed gate control signal SR1_CS_del at the fourth terminal 748 also by delaying the second transition based on the adjusted interval.

The switch control circuit 750 operates to: receive the gate control signal SR1_CS at the second terminal 754; identify a first transition (e.g., a rising edge) of the gate control signal SR1_CS as a trigger start signal; control CS₅_CS at the third terminal 755 and CS₇_CS at the fourth terminal 756 responsive to the trigger start signal to perform a first charge transfer operation as described herein; receive a trigger end signal at the first terminal 752, indicating the first charge transfer operation ends, and controlling CS₅_CS at the third terminal 755 and CS₇_CS to turn off the first switch SW5 and the second switch SW7; after the first charge transfer operation ends, control CS₈_CS at the fifth terminal 758 to sample the voltage of the inductor Iᵣₑₛ using the capacitor C_{SAMP}, resulting in Vsample; after Vsample is obtained, control CS₉_CS at the sixth terminal 760 to reset the charge on the capacitor C_{SAMP} to V_{PRE} provided by the voltage source 706; identify a second transition (e.g., falling edge) of the gate control signal SR1_CS as another trigger start signal; control CS₅_CS at the fourth terminal 724 and CS₇_CS at the fifth terminal 726 responsive to the other trigger start signal to perform a second charge transfer operation as described herein; receive a trigger end signal at the first terminal 752, indicating the second charge transfer operation ends, and controlling CS₅_CS at the third terminal 755 and CS₇_CS to turn off the first switch SW5 and the second switch SW7.

The resonant gate driver 104D and related charge transfer operations enables some recycling of the charge in charging/discharging the gate terminal 704, which improves efficiency of a power conversion system. With the back-to-back diode arrangement of the first switch SW5 and the second switch SW7, charging the inductor Lᵣₑₛ via the pull-up switch PU_SW is avoided, which reduces charge loss through the resistive path of the pull-up switch PU_SW.

The resonant gate driver 104E of FIG. 8 is an example of the resonant gate driver 104A in FIG. 2 and includes some of the components of the resonant gate driver 104C of FIG. 5 and the resonant gate driver 104D of FIG. 7 including the first pull-up switch PU_SW1, the first pull-down switch PD_SW1, the second pull-up switch PU_SW2, the second pull-down switch PU_SW2, the first switch SW5, the inductor Lᵣₑₛ, the second switch SW7, the third switch SW6, the capacitor Cᵣₑₛ, the fourth switch SW8, the fifth switch SW9, the voltage source 706, a first inverter 708A, and a second inverter 708B.

In the example of FIG. 8, the resonant gate driver 104E also includes a controller 816 (sometimes referred to as a gate driver controller herein). The controller 816 has a first terminal 818, a second terminal 819, a third terminal 820, a fourth terminal 822, a fifth terminal 824, a sixth terminal 826, a seventh terminal 828, an eighth terminal 830, a ninth terminal 832, a tenth terminal 834. In the example of FIG. 8, the controller 816 includes a delay circuit 840 and a switch control circuit 860. The delay circuit 840 has a first terminal 842, a second terminal 844, a third terminal 846, a fourth terminal 848, a fifth terminal 850, a sixth terminal 852, and a seventh terminal 854. The switch control circuit 860 has a first terminal 862, a second terminal 864, a third terminal 866, a fourth terminal 868, a fifth terminal 870, a sixth terminal 872, a seventh terminal 874, an eighth terminal 876, and a ninth terminal 878. In some examples, the resonant gate driver 104E may also include the pre-charge switch SW_{PRE} described in FIGS. 4 and 5. In such case, the controller 816 may include an additional terminal to provide SW_{PRE}_CS.

In the example of FIG. 8, the first terminal of the first pull-up switch PU_SW1 is coupled to a V_{DD} terminal 802. The control terminal of the first pull-up switch PU_SW1 is coupled to the fifth terminal 824 of the controller 816. The second terminal of the first pull-up switch PU_SW1 is coupled to the first terminal of the first pull-down switch PD_SW1 and a first gate terminal 804A. The control terminal of the first pull-down switch PD_SW1 is coupled to the second terminal of the first inverter 708A. The second terminal of the first pull-down switch PD_SW1 is coupled to ground or a ground terminal. The first terminal of the first inverter 708A is coupled to the fifth terminal 824 of the controller 816.

The first terminal of the second pull-up switch PU_SW2 is coupled to the V_{DD} terminal 802. The control terminal of the second pull-up switch PU_SW2 is coupled to the fourth terminal 822 of the controller 816. The second terminal of the second pull-up switch PU_SW2 is coupled to the first terminal of the second pull-down switch PD_SW2 and a second gate terminal 804B. The control terminal of the second pull-down switch PD_SW2 is coupled to the second terminal of the second inverter 708B. The second terminal of the second pull-down switch PD_SW2 is coupled to ground or a ground terminal. The first terminal of the second inverter 708B is coupled to the fourth terminal 822 of the controller 816.

The first gate terminal 804A is coupled to the first terminal of the first switch SW5. The control terminal of the first switch SW5 is coupled to the sixth terminal 826 of the controller 816. The second terminal of the first switch SW5 is coupled to the first terminal of the inductor Lᵣₑₛ. The second gate terminal 804B is coupled to the first terminal of the third switch SW6. The control terminal of the third switch SW6 is coupled to the seventh terminal 828 of the controller 816. The second terminal of the third switch SW6 is coupled to the first terminal of the inductor Lᵣₑₛ. The second terminal of the inductor Lᵣₑₛ is coupled to the first terminal of the second switch SW7. The control terminal of the second switch SW7 is coupled to the eighth terminal 830 of the controller 816. The second terminal of the second switch SW7 is coupled to the first terminal of the capacitor Cᵣₑₛ. The second terminal of the capacitor Cᵣₑₛ is coupled to ground or a ground terminal.

As shown, the first terminal of the fourth switch SW8 is coupled to the second terminal of the inductor Lᵣₑₛ. The control terminal of the fourth switch SW8 is coupled to the ninth terminal 832 of the controller 816. The second terminal of the fourth switch SW8 is coupled to the first terminal of the fifth switch SW9 and to the first terminal of the capacitor C_{SAMP}. The control terminal of the fifth switch SW9 is coupled to the tenth terminal 834 of the controller 816. The second terminal of the fifth switch SW9 is coupled to the first terminal of the voltage source 706. The second terminal of the voltage source 706 is coupled to ground or a ground terminal.

In the example of FIG. 8, the charge on the capacitor C_{SAMP} sets the voltage Vsample and is used as a delay control input signal to the controller 816. The third terminal 820 of the controller 816 is coupled to the first terminal of the capacitor C_{SAMP} and to the third terminal 846 (a delay control input) of the delay circuit 840. The first terminal 842 of the delay circuit 840 is coupled to first terminal 818 of the controller 816. The second terminal 844 of the delay circuit 840 is coupled to the second terminal 819 of the controller 816. The fourth terminal 848 of the delay circuit 840 is coupled to the third terminal 866 of the switch control circuit 860. The fifth terminal 850 of the delay circuit 840 is coupled to the fourth terminal 868 of the switch control circuit 860. The sixth terminal 852 of the delay circuit 840 is coupled to the fourth terminal 822 of the controller 816. The seventh terminal 854 of the delay circuit 840 is coupled to the fifth terminal 824 of the controller 816. The first terminal 862 of the switch control circuit 860 is coupled to the first terminal 818 of the controller 816. The second terminal 864 of the switch control circuit 860 is coupled to the second terminal 819 of the controller 816. The fifth terminal 870 of the switch control circuit 860 is coupled to the sixth terminal 826 of the controller 816. The sixth terminal 872 of the switch control circuit 860 is coupled to the seventh terminal 828 of the controller 816. The seventh terminal 874 of the switch control circuit 860 is coupled to the eighth terminal 830 of the controller 816. The eighth terminal 876 of the switch control circuit 860 is coupled to the ninth terminal 832 of the controller 816. The ninth terminal 878 of the switch control circuit 860 is coupled to the tenth terminal 834 of the controller 816. As to be described below, delay circuit 840 together with the capacitor C_{SAMP} and the fourth switch SW8 form a feedback control loop to set the pulse widths of SW₅_CS, SW₇_CS, and SW₆_CS to end the charge transfer operation when the inductor current I_{L} is at or close to zero.

In operation, the resonant gate driver 104E controls the voltage (Vgate1) at the first gate terminal 804A by selectively: connecting the first gate terminal 804A to V_{DD} or ground using the first pull-up switch PU_SW1 and the first pull-down switch PD_SW1; connecting the first gate terminal 804A to the inductor Lᵣₑₛ via the first switch SW5; and connecting the first gate terminal 804A to the capacitor Cᵣₑₛ via the inductor Lᵣₑₛ using first switch SW5 and the second switch SW7. Vgate1 is used to control a first power conversion system switch having the first gate terminal 804A, such as the first synchronous rectifier switch SR1_SW described herein.

The resonant gate driver 104E also controls the voltage (Vgate2) at the second gate terminal 804B by selectively: connecting the second gate terminal 804B to V_{DD} or ground using the second pull-up switch PU_SW2 and the second pull-down switch PD_SW2; connecting the second gate terminal 804B to the inductor Lᵣₑₛ via the third switch SW6; and connecting the second gate terminal 804B to the capacitor Cᵣₑₛ via the inductor Lᵣₑₛ using third switch SW6 and the second switch SW7. Vgate2 is used to control a second power conversion system switch having the second gate terminal 804B, such as the second synchronous rectifier switch SR2_SW described herein.

In the example of FIG. 8, the controller 816 operates to: receive a first gate control signal SR1_CS at the first terminal 818; identify a first transition (e.g., rising edge) of the first gate control signal SR1_CS as a first trigger start signal (Trigger start1); control CS₅_CS at the sixth terminal 826 and CS₇_CS at the eighth terminal 830 responsive to the first trigger start signal to perform a first charge transfer operation as described herein; generate a trigger end signal (Trigger end1) after a first interval has elapsed from the first transition, which signals that the first charge transfer operation ends; after the first charge transfer operation ends, control CS₈_CS at the ninth terminal 832 to sample the voltage of the inductor Iᵣₑₛ using the capacitor C_{SAMP}, resulting in Vsample; provide a first delayed gate control signal SR1_CS_del at the fifth terminal 824 after the first interval ends and after sampling ends.

After sampling ends, the controller 816 also determines/adjusts the first interval based on Vsample. The controller 816 also determines/adjusts the duration of a second interval based on Vsample. In some examples, the adjustment of the duration of the second interval can be made independently from the adjustment of the duration of the first interval. For example, as to be described below, the first and second intervals can be set by two separate sets of delay cells. The controller 816 then controls CS₈_CS at the ninth terminal 832 to reset the charge on the capacitor C_{SAMP} to V_{PRE} provided by the voltage source 706.

The controller 816 also operates to: identify a second transition (e.g., falling edge) of the first gate control signal SR1_CS as another first trigger start signal; control CS₅_CS at the sixth terminal 826 and CS₇_CS at the eighth terminal 830 responsive to the other first trigger start signal to perform a second charge transfer operation as described herein; generate a trigger end signal after the second interval has elapsed from the second transition, which signals that the second charge transfer operation ends.

The controller 816 also operates to: receive a second gate control signal SR2_CS at the second terminal 819; identify a third transition (e.g., rising edge) of the second gate control signal SR2_CS as a second trigger start signal (Trigger start2); control CS₅_CS at the sixth terminal 826 and CS₇_CS at the eighth terminal 830 responsive to the second trigger start signal to perform a third charge transfer operation as described herein; generate a second trigger end signal (Trigger end2) after the first interval has elapsed from the third transition, which signals that the third charge transfer operation ends; after the third charge transfer operation ends, control CS₈_CS at the ninth terminal 832 to sample the voltage of the inductor Iᵣₑₛ using the capacitor C_{SAMP}, resulting in Vsample; provide a second delayed gate control signal SR2_CS_del at the fourth terminal 822 after the first interval ends and after sampling ends.

After sampling ends, the controller 816 also determines/adjusts the first interval based on Vsample and determine the duration of a second interval. The controller 816 then controls CS₈_CS at the ninth terminal 832 to reset the charge on the capacitor C_{SAMP} to V_{PRE} provided by the voltage source 706.

The controller 816 also operates to: identify a fourth transition of the second gate control signal SR2_CS as another second trigger start signal; control CS₅_CS at the sixth terminal 826 and CS₇_CS at the eighth terminal 830 responsive to the other second trigger start signal to perform a fourth charge transfer operation as described herein; generate another second trigger end signal after the second interval ends, which signals that the fourth charge transfer operation ends.

More specifically, the delay circuit 840 operates to: receive the first gate control signal SR1_CS having a first transition and a second transition at the first terminal 842; provide the first trigger end signal at the fourth terminal 848 and provide a delayed gate control signal SR1_CS_del at the seventh terminal 854 as delayed versions of the first transition delayed based on the aforementioned first interval and of the second transition delayed based on the aforementioned second interval; receive the second gate control signal SR2_CS having a third transition and fourth transition at the second terminal 844; provide the second trigger end signal at the fifth terminal 850 and provide a delayed gate control signal SR2_CS_del at the sixth terminal 852 delaying delayed versions of the third transition based on the first interval and of the fourth transition delayed based on the aforementioned second interval. The delay circuit 840 also operates to receive Vsample at the third terminal 846; and adjust the durations of the first and second intervals responsive to Vsample.

The switch control circuit 860 operates to: receive the first gate control signal SR1_CS at the first terminal 862; identify the first gate control signal SR1_CS being asserted as a first trigger start signal (Trigger start1); control CS₅_CS at the fifth terminal 870 and CS₇_CS at the seventh terminal 874 responsive to a first trigger start signal to perform a first charge transfer operation as described herein; receive a first trigger end signal (Trigger end1) at the third terminal 866, indicating the first charge transfer operation ends; control CS₅_CS at the fifth terminal 870 and CS₇_CS at the seventh terminal 874 to turn off the first switch SW5 and the second switch SW7 responsive to the first trigger end signal; after the first charge transfer operation ends, control CS₈_CS at the ninth terminal 832 to sample the voltage of the inductor Iᵣₑₛ using the capacitor C_{SAMP}, resulting in Vsample; after Vsample is obtained, control CS₉_CS at the ninth terminal 878 to reset the charge on the capacitor C_{SAMP} to V_{PRE} provided by the voltage source 706; identify the first gate control signal SR1_CS being de-asserted as another first trigger start signal; control CS₅_CS at the fifth terminal 870 and CS₇_CS at the seventh terminal 874 responsive to the other first trigger start signal to perform a second charge transfer operation as described herein; receive another first trigger end signal at the third terminal 866, indicating the second charge transfer operation ends; and control CS₅_CS at the fifth terminal 870 and CS₇_CS at the seventh terminal 874 to turn off the first switch SW5 and the second switch SW7 responsive to the other first trigger end signal.

The switch control circuit 860 also operates to: receive the second gate control signal SR2_CS at the second terminal 864; identify the second gate control signal SR1_CS being asserted as a second trigger start signal (Trigger start2); control CS₅_CS at the fifth terminal 870 and CS₇_CS at the seventh terminal 874 responsive to the trigger start signal to perform a third charge transfer operation as described herein; receive a second trigger end signal (Trigger end2) at the fourth terminal 868, indicating the third charge transfer operation ends; control CS₅_CS at the fifth terminal 870 and CS₇_CS at the seventh terminal 874 to turn off the first switch SW5 and the second switch SW7 responsive to the second trigger end signal; after the third charge transfer operation ends, control CS₈_CS at the ninth terminal 832 to sample the voltage of the inductor Iᵣₑₛ using the capacitor C_{SAMP}, resulting in Vsample; after Vsample is obtained, control CS₉_CS at the ninth terminal 878 to reset the charge on the capacitor C_{SAMP} to V_{PRE} provided by the voltage source 706; identify the second gate control signal SR2_CS being de-asserted as another second trigger start signal; control CS₅_CS at the fifth terminal 870 and CS₇_CS at the seventh terminal 874 responsive to the other second trigger start signal to perform a fourth charge transfer operation as described herein; receive another second trigger end signal at the third terminal 866, indicating the fourth charge transfer operation ends; and control CS₅_CS at the fifth terminal 870 and CS₇_CS at the seventh terminal 874 to turn off the first switch SW5 and the second switch SW7 responsive to the other second trigger end signal.

The resonant gate driver 104E and related charge transfer operations enables some recycling of the Vgate1 energy, which improves efficiency of a power conversion system. With the back-to-back diode arrangement of the first switch SW5 and the second switch SW7, charging the inductor Lᵣₑₛ via the first pull-up switch PU_SW1 is avoided, which reduces charge loss through the resistive path of the first pull-up switch PU_SW1. The resonant gate driver 104E and related charge transfer operations also enables some recycling of the Vgate2 energy, which improves efficiency of a power conversion system. With the back-to-back diode arrangement of the third switch SW6 and the second switch SW7, charging the inductor Lᵣₑₛ via the second pull-up switch PU_SW2 is avoided, which reduces charge loss through the resistive path of the second pull-up switch PU_SW2.

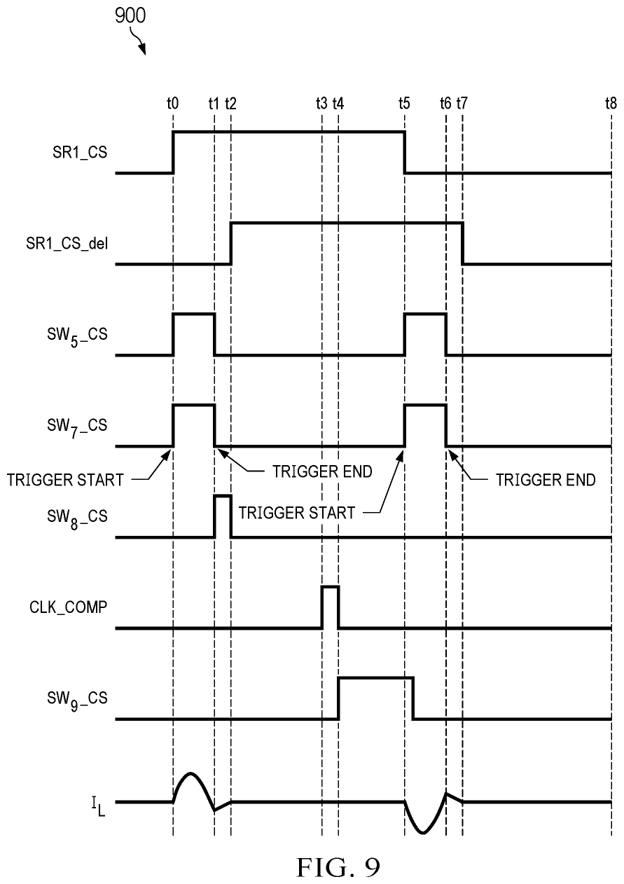

FIG. 9 is graph 900 representing operations of an example power conversion system. In the graph 900, waveforms are illustrated for the gate control signal SR1_CS, the delayed gate control signal SR1_CS_del, SW₅_CS, SW₇_CS, SW₈_CS, a comparator clock signal (CLK_COMP), SW₉_CS, and I_{L}. At time to, the gate control signal SR1_CS is asserted. In response, SW₅_CS and SW₇_CS are asserted (to turn on the first switch SW5 and the second switch SW7) resulting in positive current flow of I_{L} (the current through the inductor Lᵣₑₛ) during a first charge transfer operation as described herein. At time t1, SW₅_CS and SW₇_CS are de-asserted when I_{L} returns to zero to turn off the first switch SW5 and the second switch SW7 indicating the first charge transfer operation ends. Also, at time t1, SW₈_CS is asserted to enable C_{SAMP} to sample the voltage at the second terminal of the inductor Lᵣₑₛ, resulting in Vsample described in FIGS. 7 and 8. As shown, from time t1 to time t2, I_{L} is slightly negative before returning to zero. Vsample is used to detect whether I_{L} returns to about zero at time t2.

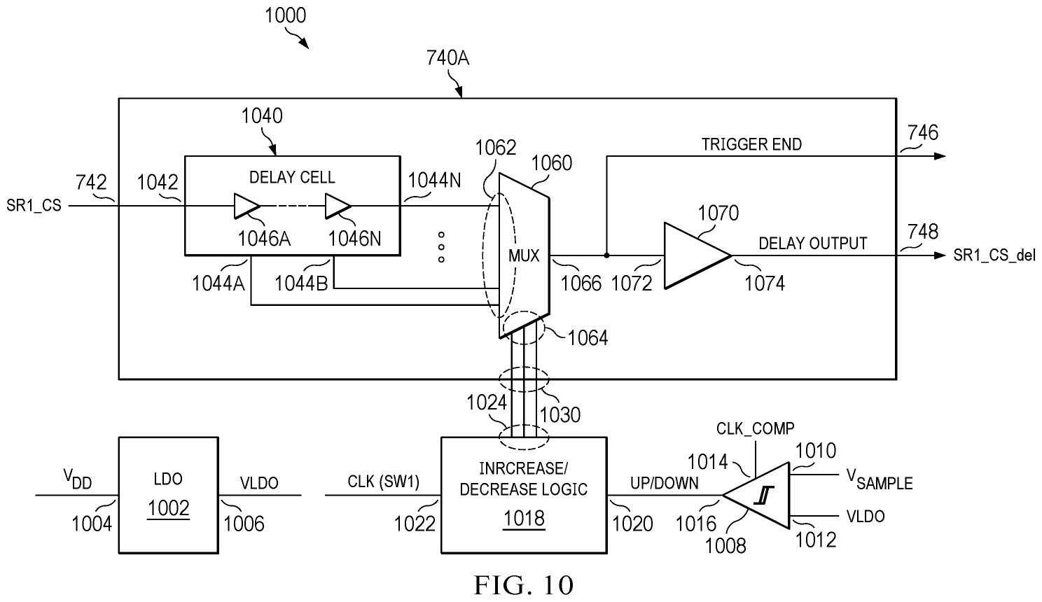

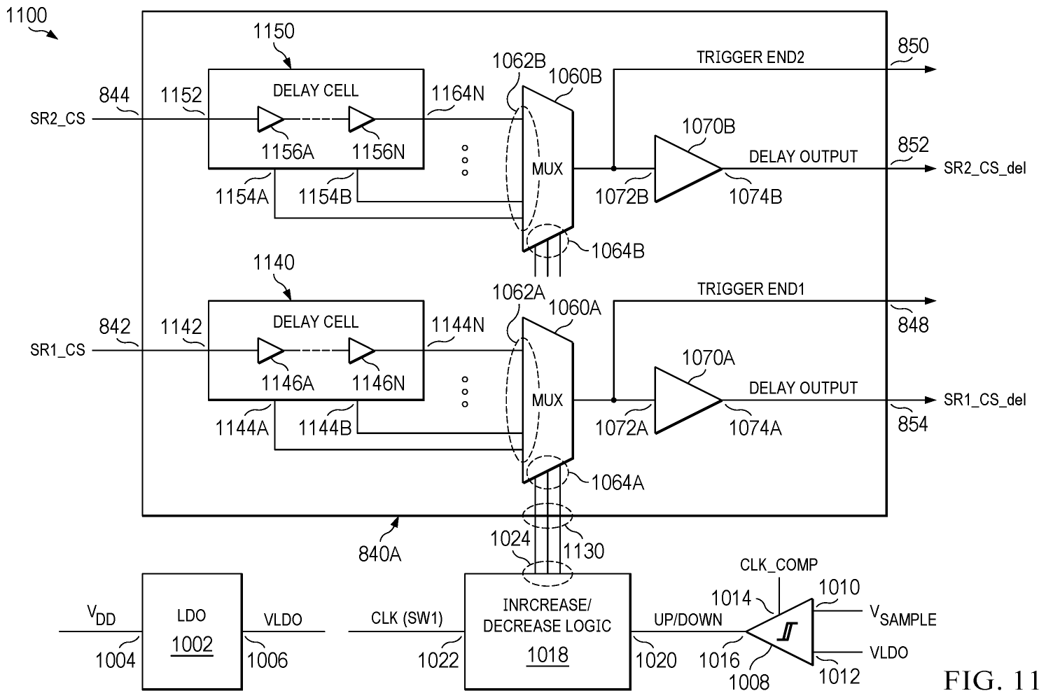

At time t2, SR1_CS_del is asserted after SW₈_CS is de-asserted and the sampling of the voltage at the second terminal of the inductor Lᵣₑₛ ends. With SR1_CS_del asserted, a pull-up operation is performed and a power conversion system switch may be turned on and described herein. At time t3, CLK_COMP is asserted, which causes Vsample to be compared with a reference voltage (e.g., VLDO in FIGS. 10 and 11). The comparison result is used to adjust the delay between subsequent transitions of SR1_CS and SR1_CS_del.

At time t4, CLK_COMP is de-asserted and SW₉_CS is asserted to reset the voltage on the capacitor C_{SAMP} (e.g., to V_{PRE} provided by the voltage source 706 in FIGS. 7 and 8). At time t5, the gate control signal SR1_CS is de-asserted. In response, SW₅_CS and SW₇_CS are asserted (to turn on the first switch SW5 and the second switch SW7) resulting is a negative current flow of I_{L} (the current through the inductor Lᵣₑₛ) during a second charge transfer operation as described herein. After time t5 and before time t6, SW₉_CS is de-asserted indicating the voltage on C_{SAMP} has been reset. At time t6, SW₅_CS and SW₇_CS are de-asserted (to turn off the first switch SW5 and the second switch SW7) when I_{L} returns to zero indicating the second charge transfer operation ends. As shown, from time t6 to time t7, I_{L} is slightly positive before returning to zero. After I_{L} returns to about zero at time t7, SR1_CS_del is de-asserted.

FIGS. 10 and 11 are schematic diagrams 1000 and 1100 showing example control loop components for a resonant gate driver. In the diagram 1000 of FIG. 10, the example control loop components include a delay circuit 740A to set the delay interval of, for example, the rising edges of SR1_CS, which can be used to generate the rising edges of SR1_CS_del. The example control loop components also include a low-dropout regulation (LDO) 1002, a comparator 1008, and increment/decrement logic 1018. The LDO 1002 has a first terminal 1004 and a second terminal 1006. The comparator 1008 has a first terminal 1010, a second terminal 1012, a third terminal 1014, and a fourth terminal 1016. The increment/decrement logic 1018 has a first terminal 1020, a second terminal 1022, and a set of third terminals 1024. In some examples, a resonant gate driver may include another delay circuit 740A, another comparator 1008, and another increment/decrement logic 1018 (not shown) to set the delay interval of, for example, the falling edges of SR1_CS, which can be used to generate the falling edges of SR1_CS_del.

The delay circuit 740A can be part of the delay circuit 740 in FIG. 7. In the example of FIG. 10, the delay circuit 740A has the first terminal 742, a set of terminals 1030, the third terminal 746, and the fourth terminal 748. The set of terminals 1030 is an example of or replaces the second terminal 744 in FIG. 7. In the example of FIG. 10, the delay circuit 740A includes a delay cell 1040, a multiplexer 1060, and a buffer circuit 1070. The delay cell 1040 has a first terminal 1042, and a set of second terminals 1044A to 1044N. The delay cell 1040 includes a set of delay elements 1046A to 1046N. The multiplexer 1060 has a set of first terminals 1062, a set of control terminals 1064, and an output terminal 1066. The buffer circuit 1070 has a first terminal 1072 and a second terminal 1074.

In the example of FIG. 10, the first terminal 742 of the delay circuit 740A is coupled to the first terminal 1042 of the delay cell 1040. The set of second terminals 1044A to 1044N of the delay cell 1040 are coupled to respective terminals of the set of first terminals 1062 of the multiplexer 1060. The set of control terminals 1064 of the multiplexer 1060 is coupled to the set of terminals 1030 of the delay circuit 740A. Based on the state of the control terminals 1064, the output of one of the delay elements in delay cell 1040 can be selected, which sets the delay introduced by delay cell 1040. The output terminal 1066 of the multiplexer 1060 is coupled to the first terminal 1072 of the buffer circuit 1070 and to the third terminal 746 of the delay circuit 740A. The second terminal 1074 of the buffer circuit 1070 is coupled to the fourth terminal 748 of the delay circuit 740A.

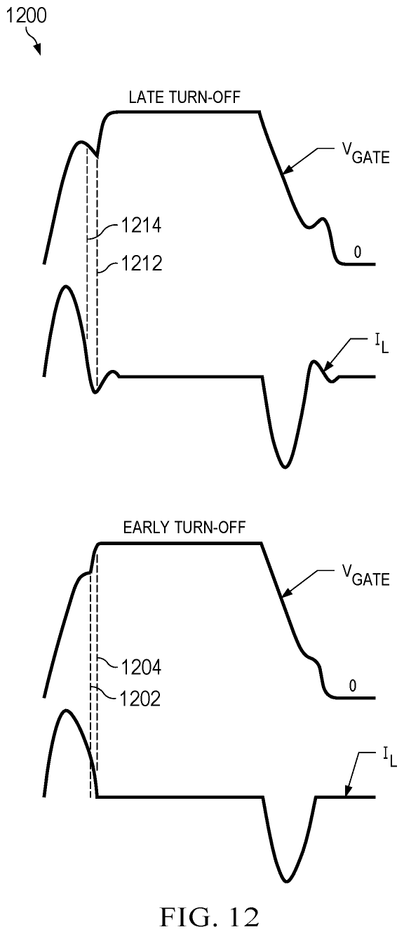

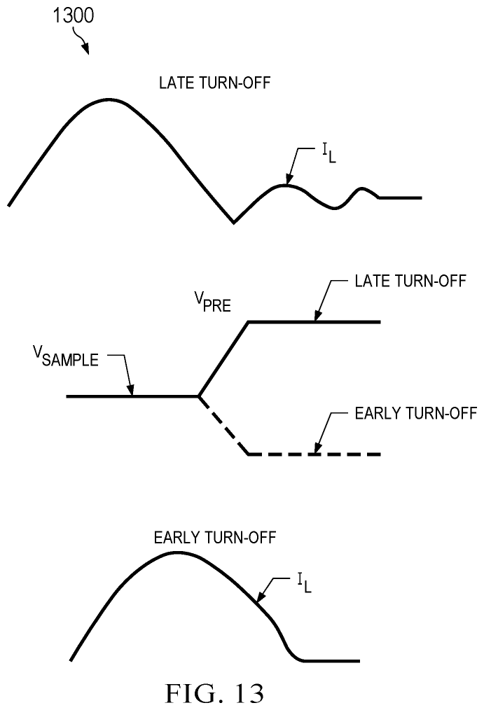

The first terminal 1004 of the LDO 1002 is coupled to a V_{DD} source (e.g., the VDD terminal 702 in FIG. 7). The second terminal 1006 of the LDO 1002 is coupled to the second terminal 1012 of the comparator 1008. The first terminal 1010 of the comparator receives Vsample (e.g., via connecting to the first terminal of the capacitor C_{SAMP} in FIG. 7). The third terminal 1014 of the comparator is coupled to a clock source (not shown) and receive CLK_COMP. The comparator can be activated to perform a comparison responsive to CLK_COMP. The fourth terminal 1016 of the comparator 1008 is coupled to the first terminal 1020 of the increment/decrement logic 1018. The second terminal 1022 of the increment/decrement logic 1018 is coupled to another clock source (not shown) and receives a clock signal CLK (SW1), which can clock the sequential logic circuits of the increment/decrement logic 1018. The set of third terminal 1024 of the increment/decrement logic 1018 is coupled to the set of terminals 1030 of the delay circuit 740A. Increment/decrement logic 1018 can increment/decrement a count value representing a delay interval responsive to the output of the comparator. As to be shown in FIG. 12 and FIG. 13, if turn-off is late (pulse width too long) and inductor current I_{L} becomes negative when the switches are turned off, inductor Lᵣₑₛ can be charging, and Vsample exceeds VLDO. Accordingly, the increment/decrement logic 1018 can decrement the count value (and the delay interval) to reduce the pulse width. On the other hand, if turn-off is early (pulse width too short), inductor current I_{L} becomes positive, inductor Lᵣₑₛ can be discharging, and Vsample can be below VLDO. Accordingly, the increment/decrement logic 1018 can increment the count value (and the delay interval) to increase the pulse width.

The control loop components of the diagram 1000 operate to provide a delay control input (the output of the increment/decrement logic 1018) to the delay circuit 740A responsive to a comparison of Vsample and VLDO. Based on the delay control input, the delay circuit 740A operates to: select a delay output interval introduced by the delay cell 1040 using the multiplexer 1060. The output of the multiplexer 1060 is a delayed signal based on gate control signal SR1_CS and the selected delay. The delayed signal is provided as a trigger end signal to trigger the end of SW₅_CS and SW₇_CS pulses by switch control circuits 750/860. The delayed signal is also provided to the first terminal 1072 of the buffer circuit 1070, which further delays the delayed signal by an additional delay interval to generate the delayed gate control signal SR1_CS_del. The switch control circuits 750/860 can also have a buffer circuit that introduces the same delay as buffer circuit 1070, and generate SW₈_CS as a pulse having the pulse width defined by that delay, responsive to a trigger end signal, for the fourth (sampling) switch SW8, so that the pulse SW₈_CS is between the ends of SW₅_CS/SW₈_CS and the start of delayed gate control signal SR1_CS_del. With such arrangements, the sampling can start after the charge transfer operation ends. The sampling can end before the gate driver is enabled to prevent the gate driver from interfering with the sampling.

In the schematic diagram 1100 of FIG. 11, the example control loop components include a delay circuit 840A, the LDO 1002, the comparator 1008, and the increment/decrement logic 1018. The delay circuit 840A is an example of the delay circuit 840 in FIG. 8. In the example of FIG. 11, the delay circuit 840A has the first terminal 842, the second terminal 844, a set of terminals 1130, the fourth terminal 848, the fifth terminal 850, the sixth terminal 852, and the seventh terminal 854. The set of terminals 1130 is an example of or replaces the third terminal 846 in FIG. 8. In the example of FIG. 11, the delay circuit 840A includes a first delay cell 1140, a second delay cell 1150, a first multiplexer 1060A, a second multiplexer 1060B, a first buffer circuit 1070A, and a second buffer circuit 1070B, to set the delay intervals of the rising edges of SR1_CS and SR2_CS, which can be used to generate, respectively, the rising edges of SR1_CS_del and SR2_CS_del. The resonant gate driver may include another delay circuit 840A, another comparator 1008, and another increment/decrement logic 1018 (not shown) to set the delay intervals of the falling edges of SR1_CS and SR2_CS, which can be used to generate, respectively, the falling edges of SR1_CS_del and SR2_CS_del.

The first delay cell 1140 has a first terminal 1142, and a set of second terminals 1144A to 1144N. The first delay cell 1140 includes a set of delay elements 1146A to 1146N. The second delay cell 1150 has a first terminal 1152, and a set of second terminals 1154A to 1154N. The second delay cell 1150 includes a set of delay elements 1156A to 1156N. The first multiplexer 1060A has a set of first terminals 1062A, a set of control terminals 1064A, and an output terminal 1066A. The second multiplexer 1060B has a set of first terminals 1062B, a set of control terminals 1064B, and an output terminal 1066B. The first buffer circuit 1070A has a first terminal 1072A and a second terminal 1074A. The second buffer circuit 1070B has a first terminal 1072B and a second terminal 1074B.

In the example of FIG. 11, the first terminal 842 of the delay circuit 840A is coupled to the first terminal 1142 of the first delay cell 1140. The set of second terminals 1144A to 1144N of the first delay cell 1140 are coupled to respective terminals of the set of first terminals 1062A of the first multiplexer 1060A. The set of control terminals 1064A of the first multiplexer 1060A is coupled to the set of terminals 1130 of the delay circuit 840A. The output terminal 1066A of the first multiplexer 1060A is coupled to the first terminal 1072A of the first buffer circuit 1070A and to the fourth terminal 848 of the delay circuit 840A. The second terminal 1074A of the first buffer circuit 1070A is coupled to the seventh terminal 854 of the delay circuit 840A.

The second terminal 844 of the delay circuit 840A is coupled to the first terminal 1152 of the second delay cell 1150. The set of second terminals 1154A to 1154N of the second delay cell 1150 are coupled to respective terminals of the set of first terminals 1062B of the second multiplexer 1060B. The set of control terminals 1064B of the second multiplexer 1060B is coupled to the set of terminals 1130 of the delay circuit 840A. The output terminal 1066B of the second multiplexer 1060B is coupled to the first terminal 1072B of the second buffer circuit 1070B and to the fifth terminal 850 of the delay circuit 840A. The second terminal 1074B of the second buffer circuit 1070B is coupled to the sixth terminal 852 of the delay circuit 840A.

In the example of FIG. 11, LDO 1002, the comparator 1008, and the increment/decrement logic 1018 are arranged is in FIG. 10, where the output of the increment/decrement logic 1018 is provided to the set of terminals 1130 of the delay circuit 840A.

The control loop components of the schematic diagram 1100 operate to provide delay control input (the output of the increment/decrement logic 1018) responsive to a comparison of Vsample and VLDO. Based on the delay control input, the delay circuit 840A operates to: select a delay interval provided by the first delay cell 1140 using the first multiplexer 1060A. The output of the first multiplexer 1060A is a first delayed signal based on the first gate control signal SR1_CS and the selected delay. In some examples, the first delayed signal is provided to the fourth terminal 848 of the delay circuit 840A as a first trigger end signal. The first delayed signal is also provided to the first terminal 1072A of the first buffer circuit 1070A, which adjusts a voltage level and/or current level of the first delayed signal. The output of the first buffer circuit 1070A is the delayed first gate control signal SR1_CS_del.

Based on the delay control input, the delay circuit 840A also operates to: select a delay interval provided by the second delay cell 1150 using the second multiplexer 1060B. The output of the second multiplexer 1060B is a second delayed signal based on the second gate control signal SR2_CS and the selected delay. In some examples, the second delayed signal is provided to the fifth terminal 850 of the delay circuit 840A as a second trigger end signal. The second delayed signal is also provided to the first terminal 1072B of the second buffer circuit 1070B, which adjusts a voltage level and/or current level of the second delayed signal. The output of the second buffer circuit 1070B is the delayed second gate control signal SR2_CS_del.

FIGS. 12 and 13 are graphs 1200 and 1300 representing operations of an example power conversion system. In the graph 1200 of FIG. 12, Vgate and I_{L} waveforms are represented illustrating the effect of late turn-off and early turn-off of a charge transfer operation. With early turn-off at time 1202 relative to a target turn-off time 1204, Vgate does not rise as high as it could, which increases power consumption of subsequent pull-up operations. With late turn-off at time 1212 relative to a target turn-off time 1214, Vgate drops after reaching a maximum for the charge transfer operation, which also increases power consumption of subsequent pull-up operations.

In the graph 1300 of FIG. 13, I_{L} waveforms are represented illustrating the effect of late turn-off and early turn-off of a charge transfer operation. With early turn-off, less of the available I_{L} used to charge Vgate. With late turn-off, I_{L} oscillates, resulting in undesirable losses to Vgate. As illustrated in graph 1300, a Vsample level above V_{PRE} indicates a late turn-off, while a Vsample level below V_{PRE} indicates an early turn-off. As described herein, Vsample or a related delay control input signal is used by control circuitry to adjust the delay between a trigger start signal and a trigger end signal to control when charge transfer operations begin and end.

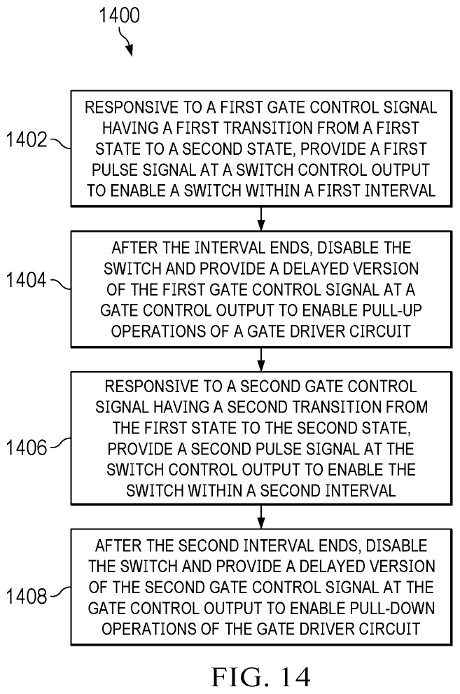

FIG. 14 is a flowchart illustrating an example control method 1400 for a power conversion system. The control method 1400 may be performed, for example, for the control circuit 102 in FIG. 1, the control circuit 102A in FIG. 2, the controller 416 in FIG. 4, the controller 516 in FIG. 5, the controller 716 in FIG. 7, or the controller 816 in FIG. 8). As shown, the control method 1400 includes, responsive to a first gate control signal (e.g., the gate control signal SR1_CS) having a first transition from a first state to a second state, providing a first pulse signal (e.g., SW₇_CS and/or SW₅_CS) at a switch control output to enable a switch (e.g., the first switch SW5 and/or the second switch SW7) within a first interval (e.g., a first charge transfer interface such as the first interval INT1 described herein) at block 1402. At block 1404, after the interval ends, disable the switch (e.g., the first switch SW5 and/or the second switch SW7) and provide a delayed version of the first gate control signal (e.g., the delayed gate control signal SR1_CS_del) at a gate control output (e.g., the gate terminal 704 in FIG. 7, the first gate terminal 804A in FIG. 8, or the second gate terminal 804B in FIG. 8) to enable pull-up operations of a gate driver circuit (e.g., the driver circuit 406 in FIG. 4, the first driver circuit 406A in FIG. 5, the second driver circuit 406B in FIG. 5, or related components in FIGS. 7 and 8).

At block 1406, responsive to a second gate control signal (e.g., the gate control signal SR1_CS) having a second transition from the first state to the second state, provide a second pulse signal (e.g., the first switch SW5 and/or the second switch SW7) at the switch control output to enable the switch (e.g., the first switch SW5 and/or the second switch SW7) within a second interval. At block 1408, after the second interval ends, disable the switch (e.g., the first switch SW5 and/or the second switch SW7) and provide a delayed version of the second gate control signal (e.g., the delayed second gate control signal SR2_CS_del) at the gate control output to enable pull-down operations of the gate driver circuit. With the method 1400, control of first charge transfer operations, pull-up operations, second charge transfer operations, and pull-down are performed.

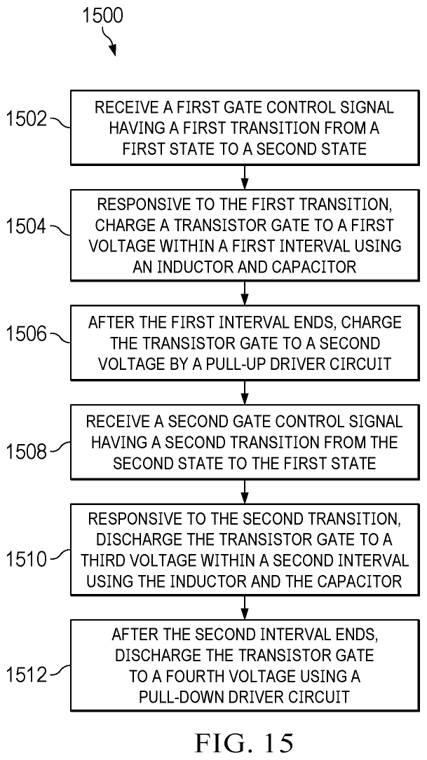

FIG. 15 is a flowchart illustrating an example method 1500 for a power conversion system. The method 1500 may be performed, for example, by the power conversion system 100 of FIG. 1, or the power conversion system 200 of FIG. 2. As shown, the method 1500 includes receiving a first gate control signal (e.g., the first gate control signal SR_CS1) having a first transition from a first state to a second state at block 1502. At block 1504, responsive to the first transition, a transistor gate is charged to a first voltage (e.g., Vᵣₑₛ−losses) within a first interval (e.g., the first interval INT1) using an inductor (e.g., the inductor Lᵣₑₛ herein) and a capacitor (e.g., the capacitor Cᵣₑₛ herein). Example transistor gates includes the gate of the low-side switch LS_SW in FIG. 1, the gate of first synchronous rectifier switch SR_SW1 in FIG. 2, or the gate of the second synchronous rectifier switch SR_SW2 in FIG. 2.

After the first interval ends, the transistor gate is charged to a second voltage (e.g., V_{DD}) by a pull-up driver circuit (e.g., by operating the pull-up switch PU_SW in FIG. 4, the first pull-up switch PU_SW1 in FIG. 5, or the second pull-up switch PU_SW2 in FIG. 5) at block 1506. At block 1508, the method 1500 includes receiving a second gate control signal (e.g., the gate control signal SR1_CS) having a second transition from the second state to the first state. At block 1510, responsive to the second transition, the transistor gate is discharged to a third voltage within a second interval (e.g., the third charge transfer INT3 related to a second charge transfer operation as in FIG. 6) using the inductor and the capacitor. At block 1512, after the second interval ends, the method 1500 includes discharging the transistor gate to a fourth voltage (e.g., GND) using a pull-down driver circuit (e.g., by operating the pull-down switch PD_SW in FIG. 4, the first pull-down switch PD_SW1 in FIG. 5, or the second pull-down switch PD_SW2 in FIG. 5).

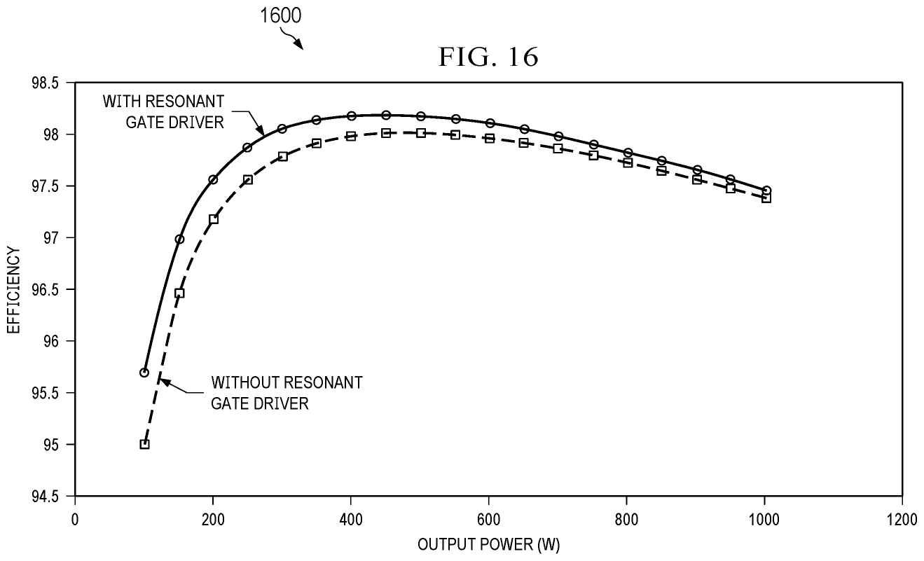

FIG. 16 is graph 1600 showing efficiency as a function of output power with and without using the examples of resonant gate drivers as described herein. As shown in graph 1600, use of a resonant gate driver as described herein improves efficiency over the entire output power range. At lower output power, the benefit of using a resonant gate driver is increased.

In this description, the term “couple” may cover connections, communications, or signal paths that enable a functional relationship consistent with this description. For example, if device A generates a signal to control device B to perform an action: (a) in a first example, device A is coupled to device B by direct connection; or (b) in a second example, device A is coupled to device B through intervening component C if intervening component C does not alter the functional relationship between device A and device B, such that device B is controlled by device A via the control signal generated by device A.

Also, in this description, the recitation “based on” means “based at least in part on.” Therefore, if X is based on Y, then X may be a function of Y and any number of other factors.

A device that is “configured to” perform a task or function may be configured (e.g., programmed and/or hardwired) at a time of manufacturing by a manufacturer to perform the function and/or may be configurable (or reconfigurable) by a user after manufacturing to perform the function and/or other additional or alternative functions. The configuring may be through firmware and/or software programming of the device, through a construction and/or layout of hardware components and interconnections of the device, or a combination thereof.

As used herein, the terms “terminal”, “node”, “interconnection”, “pin” and “lead” are used interchangeably. Unless specifically stated to the contrary, these terms are generally used to mean an interconnection between or a terminus of a device element, a circuit element, an integrated circuit, a device or other electronics or semiconductor component.

A circuit or device that is described herein as including certain components may instead be adapted to be coupled to those components to form the described circuitry or device. For example, a structure described as including one or more semiconductor elements (such as transistors), one or more passive elements (such as resistors, capacitors, and/or inductors), and/or one or more sources (such as voltage and/or current sources) may instead include only the semiconductor elements within a single physical device (e.g., a semiconductor die and/or integrated circuit (IC) package) and may be adapted to be coupled to at least some of the passive elements and/or the sources to form the described structure either at a time of manufacture or after a time of manufacture, for example, by an end-user and/or a third-party.

While the use of particular transistors is described herein, other transistors (or equivalent devices) may be used instead with little or no change to the remaining circuitry. For example, a field effect transistor (“FET”) such as an NFET or a PFET, a bipolar junction transistor (BJT—e.g., NPN transistor or PNP transistor), an insulated gate bipolar transistor (IGBT), and/or a junction field effect transistor (JFET) may be used in place of or in conjunction with the devices described herein. The transistors may be depletion mode devices, drain-extended devices, enhancement mode devices, natural transistors or other types of device structure transistors. Furthermore, the devices may be implemented in/over a silicon substrate (Si), a silicon carbide substrate (SiC), a gallium nitride substrate (GaN) or a gallium arsenide substrate (GaAs).

References may be made in the claims to a transistor's control terminal and its first and second terminals. In the context of a FET, the control terminal is the gate, and the first and second terminals are the drain and source. In the context of a BJT, the control terminal is the base, and the first and second terminals are the collector and emitter.

References herein to a FET being “ON” means that the conduction channel of the FET is present and drain current may flow through the FET. References herein to a FET being “OFF” means that the conduction channel is not present so drain current does not flow through the FET. An “OFF” FET, however, may have current flowing through the transistor's body-diode.

Circuits described herein are reconfigurable to include additional or different components to provide functionality at least partially similar to functionality available prior to the component replacement. Components shown as resistors, unless otherwise stated, are generally representative of any one or more elements coupled in series and/or parallel to provide an amount of impedance represented by the resistor shown. For example, a resistor or capacitor shown and described herein as a single component may instead be multiple resistors or capacitors, respectively, coupled in parallel between the same nodes. For example, a resistor or capacitor shown and described herein as a single component may instead be multiple resistors or capacitors, respectively, coupled in series between the same two nodes as the single resistor or capacitor.

While certain elements of the described examples are included in an integrated circuit and other elements are external to the integrated circuit, in other examples, additional or fewer features may be incorporated into the integrated circuit. In addition, some or all of the features illustrated as being external to the integrated circuit may be included in the integrated circuit and/or some features illustrated as being internal to the integrated circuit may be incorporated outside of the integrated circuit. As used herein, the term “integrated circuit” means one or more circuits that are: (i) incorporated in/over a semiconductor substrate; (ii) incorporated in a single semiconductor package; (iii) incorporated into the same module; and/or (iv) incorporated in/on the same printed circuit board.

Uses of the phrase “ground” in the foregoing description include a chassis ground, an Earth ground, a floating ground, a virtual ground, a digital ground, a common ground, and/or any other form of ground connection applicable to, or suitable for, the teachings of this description. In this description, unless otherwise stated, “about,” “approximately” or “substantially” preceding a parameter means being within +/−10 percent of that parameter or, if the parameter is zero, a reasonable range of values around zero.

Modifications are possible in the described examples, and other examples are possible, within the scope of the claims.

What is claimed is:

1. An apparatus comprising:
a gate driver circuit having a driver input and a driver output;
an inductor coupled to the driver output;
a capacitor;
a first switch coupled between the inductor and the capacitor, the first switch having a first switch control terminal;
a second switch coupled between inductor and the driver output, the second switch having a second switch control terminal; and
a controller having a gate control input, a first switch control output, a second switch control output, and a gate control output, the first switch control output coupled to the first switch control terminal, the second switch control output coupled to the second switch control terminal, and the gate control output coupled to the driver output.

2. The apparatus of claim 1, wherein the gate driver circuit is a first gate driver circuit, the driver input is a first driver input, the driver output is a first driver output, and the apparatus further comprises:
a second gate driver circuit having a second driver input and a second driver output; and
a third switch coupled between the second driver output and the inductor.

3. The apparatus of claim 2, wherein the first driver output is coupled to a first synchronous rectifier (SR) control output, and the second driver output is coupled to a second SR control output.

4. The apparatus of claim 1, wherein the controller is configured to:
responsive to a gate control signal at the gate control input, provide a pulse signal at the first and second switch control outputs to enable, respectively, the first and second switches within an interval; and
before the interval ends, disable the first and second switches; and
after disabling the first and second switches, provide a delayed version of the gate control signal at the gate control output.

5. The apparatus of claim 4, wherein the pulse signal is a first pulse signal, the interval is a first interval, the gate control signal is a first gate control signal having a first transition from a first state to a second state, and the controller configured to:
responsive to the first transition, provide the delayed version of the first gate control signal at the gate control output, the delayed version of the first gate control signal having the first transition delayed by the first interval;
receive a second gate control signal having a second transition from the second state to the first state;
responsive to the second transition, provide a delayed version of the second gate control signal at the gate control output, the delayed version of the second gate control signal having the second transition delayed by a second interval;
within the second interval, provide a second pulse signal at the first and second switch control outputs to enable the first and second switches;
before the second interval ends, disable the first and second switches; and
after disabling the first and second switches, provide the delayed version of the second gate control signal at the gate control output.

6. The apparatus of claim 5, wherein the gate driver circuit has a power terminal, a ground terminal, a pull-up switch coupled between the power terminal and the driver output, a pull-down switch coupled between the driver output and the ground terminal, each of the pull-up and pull-down switches includes a respective switch control terminal coupled to the driver input, the pull-up switch is enabled responsive to the driver input having the second state, the pull-up switch is disabled responsive to the driver input having the first state, the pull-down switch is enabled responsive to the driver input having the first state, and the pull-down switch is disabled responsive to the driver input having the second state.

7. The apparatus of claim 5, wherein the controller includes:
a delay circuit having a delay control input, a delay input, a delay output, and a trigger output, the delay control input coupled to the inductor, the delay input coupled to the gate control input, and the delay output coupled to the gate control output, the delay circuit configured to, responsive to a voltage at the delay control input, provide the delayed version of the first and second gate control signals at the delay output and provide a trigger signal at the trigger output; and
a switch control circuit having a trigger start input, a trigger end input, and the first and second switch control outputs, the trigger start input coupled to the gate control input, the trigger end input coupled to the trigger output, and the switch control circuit configured to start the first and second pulses responsive the first and second gate control signals and the end the first and second pulses responsive to the trigger signal.

8. The apparatus of claim 7, wherein the capacitor is a first capacitor, and the apparatus further comprises:
a second capacitor coupled to a ground;
a third switch coupled between the inductor and the second capacitor;
a fourth switch coupled between the second capacitor and a voltage reference;
a comparator having a first comparator input, a second comparator input, and a comparator output, the first comparator input coupled to the inductor, and the second comparator input coupled to the voltage reference, the comparator configured to generate a comparison signal representing a comparison between a sampled voltage and the voltage reference; and
a logic circuit coupled between the comparator output and the delay control input,
the controller being configured to control the second capacitor to obtain the sampled voltage between when the first and second switch control outputs transition from a third state to a fourth state, and
the logic circuit being configured to generate a delay control signal at the delay control input when the first interval ends, the delay control signal based on the comparison signal.

9. The apparatus of claim 8, wherein the delay circuit includes:
a set of delay elements, an input of a first delay element of the set of delay elements is coupled to the delay input; and
a multiplexer having inputs coupled to outputs of the set of delay elements, the multiplexer having a selection input and a multiplexor output, the selection input coupled to the delay control input, and the multiplexer output coupled to the delay output and the trigger output.

10. The apparatus of claim 8, wherein the inductor, the capacitor, the gate driver circuit, the first switch, and the second switch are part of an integrated circuit (IC).

11. The apparatus of claim 10, wherein the IC includes a semiconductor substrate on a routable lead frame (RLF), wherein the inductor is in the RLF, and the capacitor is a trench capacitor in the semiconductor substrate.

12. An apparatus comprising:
a power converter having a power converter switch, the power converter switch having a power converter switch control terminal;
a power converter control circuit coupled to the power converter switch control terminal, the power converter control circuit including:
a gate driver circuit having a driver input and a driver output;
an inductor coupled to the driver output;
a capacitor;
a first switch coupled between the inductor and the capacitor, the first switch having a first switch control terminal;
a second switch coupled between inductor and the driver output, the second switch having a second switch control terminal; and
a gate drive controller having a gate control input, a first switch control output, a second switch control output, and a gate control output, the first switch control output coupled to the first switch control terminal, the second switch control output coupled to the second switch control terminal, and the gate control output coupled to the driver output.

13. The apparatus of claim 12, wherein the power converter includes a half-bridge buck power stage that includes the power converter switch as a low-side switch, the low-side switch having zero voltage when the power converter switch control terminal is charged and discharged using the inductor and capacitor.

14. The apparatus of claim 12, wherein the power converter includes a resonant converter topology, the resonant converter topology having a half-bridge buck power stage, a resonant tank, a transformer, and a resonant converter output, the transformer having a first transformer side and second transformer side, the first transformer side coupled to the resonant tank, the power converter switch being a first synchronous rectifier switch between the second transformer side and the resonant converter output, the power converter including a second synchronous rectifier switch between the second transformer side and the resonant converter output.

15. The apparatus of claim 12, wherein the gate driver circuit is a first gate driver circuit, the driver input is a first driver input, the driver output is a first driver output, and the power converter control circuit includes:
a second gate driver circuit having a second driver input and a second driver output; and
a third switch coupled between the second driver output and the inductor.

16. The apparatus of claim 12, wherein the gate drive controller is configured to:
responsive to a gate control signal at the gate control input, provide a pulse signal at the first and second switch control outputs to enable, respectively, the first and second switches within an interval; and
before the interval ends, disable the first and second switches; and
after disabling the first and second switches, provide a delayed version of the gate control signal at the gate control output.

17. The apparatus of claim 16, wherein the pulse signal is a first pulse signal, the interval is a first interval, the gate control signal is a first gate control signal having a first transition from a first state to a second state, and the power converter control circuit is configured to:
responsive to the first transition, provide the delayed version of the first gate control signal at the gate control output, the delayed version of the first gate control signal having the first transition delayed by the first interval;
receive a second gate control signal having a second transition from the second state to the first state;
responsive to the second transition, provide a delayed version of the second gate control signal at the gate control output, the delayed version of the second gate control signal having the second transition delayed by a second interval;
before the second interval ends, disable the switch; and
after disabling the switch, provide the delayed version of the second gate control signal at the gate control output.

18. The apparatus of claim 17, wherein the gate driver circuit has a power terminal, a ground terminal, a pull-up switch coupled between the power terminal and the driver output, a pull-down switch coupled between the driver output and the ground terminal, each of the pull-up and pull-down switches includes a respective switch control terminal coupled to the driver input, the pull-up switch is enabled responsive to the driver input having the second state, the pull-up switch is disabled responsive to the driver input having the first state, the pull-down switch is enabled responsive to the driver input having the first state, and the pull-down switch is disabled responsive to the driver input having the second state.

19. The apparatus of claim 17, wherein the gate drive controller includes:
a delay circuit having a delay control input, a delay input, a delay output, and a trigger output, the delay control input coupled to the inductor, the delay input coupled to the gate control input, and the delay output coupled to the gate control output, the delay circuit configured to, responsive to a voltage at the delay control input, provide the delayed version of the first and second gate control signals at the delay output and provide a trigger signal at the trigger output; and
a switch control circuit having a trigger start input, a trigger end input, and the first and second switch control outputs, the trigger start input coupled to the gate control input, the trigger end input coupled to the trigger output, and the switch control circuit configured to start the first and second pulses responsive the first and second gate control signals and the end the first and second pulses responsive to the trigger signal.

20. The apparatus of claim 19, wherein the capacitor is a first capacitor, and the power converter control circuit further comprises:
a second capacitor coupled to a ground;
a third switch coupled between the inductor and the second capacitor;
a fourth switch coupled between the second capacitor and a voltage reference;
a comparator having a first comparator input, a second comparator input, and a comparator output, the first comparator input coupled to the inductor, and the second comparator input coupled to the voltage reference, the comparator configured to generate a comparison signal representing a comparison between a sampled voltage and the voltage reference; and
a logic circuit coupled between the comparator output and the delay control input,
the controller being configured to control the second capacitor to obtain the sampled voltage between when the first and second switch control outputs transitions from a third state to a fourth state and, when the first interval ends, the logic circuit is configured to generate a delay control signal at the delay control input based on the comparison signal.

21. A method comprising:
receiving a first gate control signal having a first transition from a first state to a second state;
responsive to the first transition, charging a transistor gate to a first voltage within a first interval using an inductor and a capacitor;
after the first interval ends, charging the transistor gate to a second voltage by a pull-up driver circuit;
receiving a second gate control signal having a second transition from the second state to the first state;
responsive to the second transition, discharging the transistor gate to a third voltage within a second interval using the inductor and the capacitor; and
after the second interval ends, discharging the transistor gate to a fourth voltage using a pull-down driver circuit.
